(19) United States
(12) Patent Application Publication
(10) Pub. No.: US 2026/0168077 A1
(43) Pub. Date: Jun. 18, 2026

(54) DEPOSITION MASK, MANUFACTURING METHOD OF DEPOSITION MASK AND ELECTRONIC DEVICE MANUFACTURED USING DEPOSITION MASK

(71) Applicant: Samsung Display Co., LTD., Yongin-si (KR)

(72) Inventors: Young Jin SONG, Yongin-si (KR); Jeong Kuk KIM, Yongin-si (KR); Seung Sok SON, Yongin-si (KR)

(21) Appl. No.: 19/293,624

(22) Filed: Aug. 7, 2025

(30) Foreign Application Priority Data
Dec. 12, 2024 (KR) 10-2024-0184839

(51) Int. Cl. C23C 14/04; H10K 59/12; H10K 71/16

(52) U.S. Cl. CPC C23C 14/042; H10K 59/1201; H10K 71/166

(57) ABSTRACT

A deposition mask includes a mask frame in which a cell opening is defined, a membrane disposed above the mask frame, and a doping layer extending in the thickness direction of the mask frame from the lower surface of the mask frame.

This application claims priority to Korean Patent Application No. 10-2024-0184839, filed on December 12, 2024, and all the benefits accruing therefrom under 35 U.S.C. §119, the content of which in its entirety is herein incorporated by reference.

### BACKGROUND

### 1. Field

The disclosure relates to a deposition mask, a manufacturing method of the deposition mask, and an electronic device manufactured using the deposition mask.

### 2. Description of the Related Art

A head mounted display (“HMD”) is an image display device that is worn on a user's head in the form of glasses or helmets to form a focus at a close distance in front of the user's eyes. The head mounted display may implement virtual reality (“VR”) or augmented reality (“AR”).

The head mounted display magnifies an image displayed on a relatively small display device by a plurality of lenses, and displays the magnified image. Therefore, the display device applied to the head mounted display needs to provide high-resolution images, e.g., images with a resolution of 3000 Pixels Per Inch (PPI) or higher. To this end, an organic light-emitting diode on silicon (“OLEDoS”), which is a high-resolution relatively small organic light-emitting display device, is used as the display device applied to the head mounted display. The OLEDoS is an image display device in which an organic light-emitting diode (“OLED”) is located on a semiconductor wafer substrate including complementary metal oxide semiconductor (“CMOS”).

In order to manufacture a display panel with a relatively high resolution of 3000 PPI or higher, a high-resolution deposition mask is desired. In an embodiment, the deposition mask may be manufactured by forming a membrane defining a plurality of pixel openings on a substrate such as a silicon wafer, and partially etching the substrate to define cell openings that expose the pixel openings.

A deposition mask may be used in a deposition process for forming organic light-emitting layers on a backplane substrate. While the deposition process is being performed, the backplane substrate may be located on the deposition mask, and a deposition source for providing a vapor deposition material may be located under the deposition mask. The vapor deposition material may be deposited on the backplane substrate through pixel openings of the deposition mask.

### SUMMARY

Features of the disclosure provide a deposition mask in which a doping layer is formed on a mask frame, thereby preventing a cell opening from being over-etched in a process of etching the cell opening in the mask frame to prevent a first rear inorganic layer and a second rear inorganic layer from protruding toward the cell opening, a manufacturing method of the deposition mask, and an electronic device manufactured using the deposition mask.

However, features of the disclosure are not restricted to those set forth herein. The above and other features of the disclosure will become more apparent to one of ordinary skill in the art to which the disclosure pertains by referencing the detailed description of the disclosure given below.

In an embodiment of the disclosure, a deposition mask includes a mask frame in which a cell opening is defined, a membrane disposed above the mask frame, and a doping layer extending in a thickness direction of the mask frame from a lower surface of the mask frame.

In an embodiment, the cell opening extends toward the membrane from the lower surface of the mask frame, and the doping layer is disposed to surround a lower end of the cell opening.

In an embodiment, the cell opening extends toward the membrane from the side of the lower surface of the doping layer, and a cross-sectional area of the cell opening in a horizontal direction is reduced toward the membrane.

In an embodiment, the membrane is divided into a mask cell region disposed above the cell opening and a grid region disposed above the mask frame excluding the cell opening, and the doping layer overlaps the grid region.

In an embodiment, the deposition mask further includes a first rear inorganic layer disposed below the mask frame and in which a first rear opening is defined, and a second rear inorganic layer disposed below the first rear inorganic layer and in which a second rear opening is defined, where the doping layer overlaps the first rear inorganic layer and the second rear inorganic layer.

In an embodiment, a lower surface of the doping layer contacts a top surface of the first rear inorganic layer.

In an embodiment, the cell opening overlaps the first rear opening and the second rear opening.

In an embodiment, the membrane includes an inorganic layer disposed above the mask frame and in which an inorganic layer opening is defined, and a nitride layer disposed above the inorganic layer and in which a plurality of pixel openings are defined, where the inorganic layer opening and the plurality of pixel openings overlap the cell opening.

In an embodiment, the doping layer is formed by doping the mask frame with one or more selected elements from boron (B), aluminum (Al), phosphorus (P), arsenic (As), and antimony (Sb).

In an embodiment of the disclosure, a manufacturing method of a deposition mask, the manufacturing method includes forming an inorganic layer above a mask frame and forming a first rear inorganic layer below the mask frame, exposing a portion of the mask frame to the outside by removing a portion of the first rear inorganic layer, forming a doping layer by doping the exposed portion of the mask frame, forming the first rear inorganic layer to cover the exposed portion of the mask frame, forming a nitride layer above the inorganic layer and forming a second rear inorganic layer below the first rear inorganic layer, defining a first rear opening to penetrate the first rear inorganic layer and defining a second rear opening to penetrate the second rear inorganic layer, forming a plurality of pixel openings to penetrate the nitride layer, defining a cell opening to penetrate the mask frame, and defining an inorganic layer opening to penetrate the inorganic layer.

In an embodiment, the exposing the portion of the mask frame to the outside by removing the portion of the first rear inorganic layer is removing the portion of the first rear inorganic layer by a wet etching process, and the portion of the mask frame exposed to the outside is a portion where the cell opening is not defined.

In an embodiment, the forming the doping layer by doping the exposed portion of the mask frame is forming the doping layer by doping the mask frame with one or more elements selected from boron (B), aluminum (Al), phosphorus (P), arsenic (As), and antimony (Sb).

In an embodiment, the forming the first rear inorganic layer to cover the exposed portion of the mask frame is forming the first rear inorganic layer below the mask frame to cover the exposed portion of the mask frame.

In an embodiment, the defining the first rear opening to penetrate the first rear inorganic layer and defining the second rear opening to penetrate the second rear inorganic layer is defining the second rear opening by penetrating the second rear inorganic layer and defining the first rear opening by penetrating the first rear inorganic layer through a wet etching process from below the second rear inorganic layer to insides of the second rear inorganic layer and the first rear inorganic layer.

In an embodiment, the defining the plurality of pixel openings to penetrate the nitride layer is defining the plurality of pixel openings by penetrating the nitride layer by a wet etching process from above the nitride layer to the inside of the nitride layer.

In an embodiment, the defining the cell opening to penetrate the mask frame is defining the cell opening by penetrating the mask frame by a wet etching process from below the mask frame to the inside of the mask frame.

In an embodiment, in the defining the cell opening to penetrate the mask frame, an etching of the mask frame is confined by the doping layer to confine an etching of the mask frame in a horizontal direction.

In an embodiment, the defining the inorganic layer opening to penetrate the inorganic layer is defining the inorganic layer opening by penetrating the inorganic layer through a wet etching process from below the inorganic layer to the inside of the inorganic layer.

In an embodiment of the disclosure, an electronic device includes a display device manufactured using a deposition mask, where the deposition mask includes a mask frame in which a cell opening is defined, a membrane disposed above the mask frame, and a doping layer extending in a thickness direction of the mask frame from a lower surface of the mask frame.

In an embodiment, the cell opening extends from the lower surface of the mask frame toward the membrane, and the doping layer is disposed to surround a lower end of the cell opening.

In accordance with the deposition mask, the manufacturing method of the deposition mask, and the electronic device manufactured using the deposition mask according to the disclosure, by forming a doping layer on a mask frame, a cell opening may be prevented from being over-etched in a process of etching the cell opening in the mask frame to prevent a first rear inorganic layer and a second rear inorganic layer from protruding toward the cell opening.

The effects in the embodiments of the disclosure are not limited to those mentioned above and more various effects are included in the following description of the disclosure.

### BRIEF DESCRIPTION OF THE DRAWINGS

The above and other advantages and features of the disclosure will become more apparent by describing in detail embodiments thereof with reference to the attached drawings, in which:

FIG. 1 is a schematic exploded perspective view showing an embodiment of a display device;

FIG. 2 is a schematic plan view illustrating the display device shown in FIG. 1;

FIG. 3 is an equivalent circuit diagram showing an embodiment of a first sub-pixel shown in FIG. 2;

FIG. 4 is a schematic plan view illustrating an embodiment of the display panel shown in FIG. 1;

FIG. 5 is a schematic enlarged plan view showing an embodiment of the display area of FIG. 4;

FIG. 6 is a schematic enlarged plan view showing another embodiment of the display area of FIG. 4;

FIG. 7 is a schematic cross-sectional view illustrating an embodiment of a display panel taken along line I1-I1’ of FIG. 5;

FIG. 8 is a schematic cross-sectional view illustrating another embodiment of a display panel taken along line I1-I1’ of FIG. 5;

FIG. 9 is a perspective view illustrating an embodiment of a head mounted display;

FIG. 10 is an exploded perspective view illustrating the head mounted display of FIG. 9;

FIG. 11 is a perspective view illustrating another embodiment of a head mounted display;

FIG. 12 is a schematic diagram illustrating an embodiment of a deposition apparatus;

FIG. 13 is a schematic bottom view illustrating the backplane substrate shown in FIG. 12;

FIG. 14 is a schematic plan view illustrating an embodiment of a deposition mask according to the disclosure;

FIG. 15 is a schematic enlarged plan view illustrating the mask cell regions shown in FIG. 14;

FIG. 16 is a schematic cross-sectional view illustrating a first embodiment of a deposition mask taken along line I2-I2’ of FIG. 15;

FIG. 17 is a diagram showing an embodiment of a state in which an inorganic layer and a first rear inorganic layer are formed on the upper and lower portions of a mask frame in a manufacturing method of a deposition mask according to the disclosure;

FIG. 18 is a diagram showing a state in which a portion of the first rear inorganic layer is removed in FIG. 17;

FIG. 19 is a diagram showing a state in which a doping layer is formed on a mask frame in FIG. 18;

FIG. 20 is a diagram showing a state in which the first rear inorganic layer is formed to cover the doping layer in FIG. 19;

FIG. 21 is a diagram showing a state in which a nitride layer is formed above the inorganic layer and a second rear inorganic layer is formed below the first rear inorganic layer in FIG. 20;

FIG. 22 is a diagram showing a state in which a first rear opening and a second rear opening are formed in FIG. 21;

FIG. 23 is a diagram showing a state in which a photo mask is disposed above the nitride layer in FIG. 22;

FIG. 24 is a diagram showing a state in which a plurality of pixel openings is defined in the nitride layer in FIG. 23;

FIG. 25 is a diagram showing a state in which a cell opening is defined in FIG. 24;

FIG. 26 is a diagram showing a state in which an inorganic layer opening is defined in FIG. 25;

FIG. 27 is a block diagram of an embodiment of an electronic device; and

FIG. 28 is schematic views of embodiments of electronic devices.

### DETAILED DESCRIPTION

Advantages and features of the disclosure and methods to achieve them will become apparent from the descriptions of embodiments hereinbelow with reference to the accompanying drawings. However, the disclosure is not limited to embodiments disclosed herein but may be implemented in various different ways. The embodiments are provided for making the disclosure of the disclosure thorough and for fully conveying the scope of the disclosure to those skilled in the art. It is to be noted that the scope of the disclosure is defined only by the claims.

As used herein, a phrase “an element A on an element B” refers to that the element A may be disposed directly on the element B and/or the element A may be disposed indirectly on the element B via another element C. Like reference numerals denote like elements throughout the descriptions. The drawing figures, dimensions, ratios, angles, numbers of elements given in the drawings are merely illustrative and are not limiting.

Although terms such as first, second, etc. are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of the disclosure.

Features of various embodiments of the disclosure may be combined partially or totally. As will be clearly appreciated by those skilled in the art, technically various interactions and operations are possible. Various embodiments may be practiced individually or in combination.

"About" or "approximately" as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term "about" can mean within one or more standard deviations, or within ± 30%, 20%, 10%, 5% of the stated value, for example.

Hereinafter, embodiments of the disclosure will be described in detail with reference to the accompanying drawings.

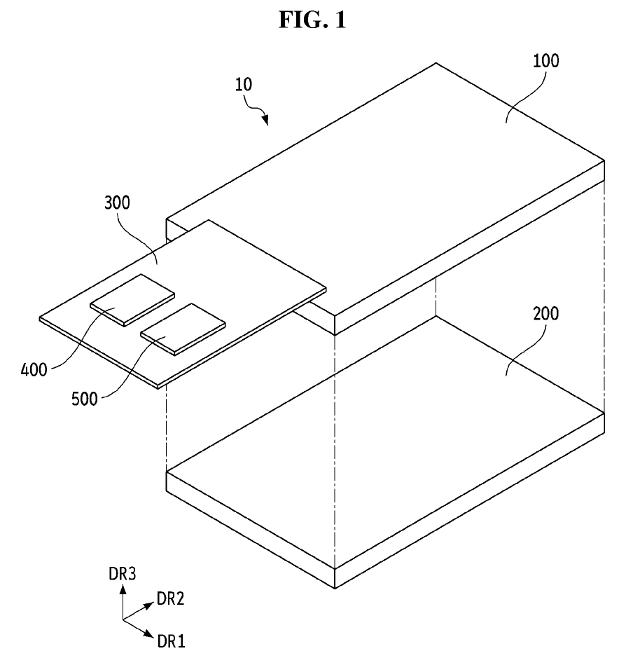

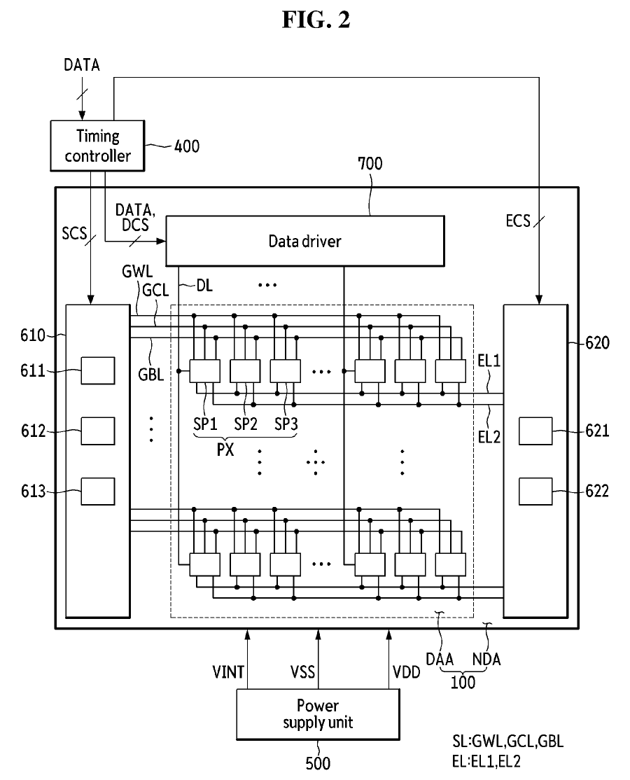

FIG. 1 is a schematic exploded perspective view showing an embodiment of a display device. FIG. 2 is a schematic plan view illustrating the display device shown in FIG. 1.

Referring to FIGS. 1 and 2, a display device 10 in an embodiment is a device displaying a moving image or a still image. The display device 10 in an embodiment may be applied to portable electronic devices such as a mobile phone, a smartphone, a tablet personal computer, a mobile communication terminal, an electronic organizer, an electronic book, a portable multimedia player (“PMP”), a navigation system, an ultra mobile personal computer (“UMPC”) or the like. In an embodiment, the display device 10 in an embodiment may be applied as a display unit of a television, a laptop, a monitor, a billboard, or an Internet-of-Things (“IoT”) terminal, for example. In an alternative embodiment, the display device 10 in an embodiment may be applied to a smart watch, a watch phone, a head mounted display (“HMD”) for implementing virtual reality and augmented reality, or the like.

The display device 10 in an embodiment includes a display panel 100, a heat dissipation layer 200, a circuit board 300, a timing control circuit 400, and a power supply circuit 500.

The display panel 100 may have a planar shape similar to a quadrilateral shape. In an embodiment, the display panel 100 may have a planar shape similar to a quadrilateral shape, having a short side of a first direction DR1 and a long side of a second direction DR2 intersecting the first direction DR1, for example. In the display panel 100, a corner where a short side in the first direction DR1 and a long side in the second direction DR2 meet may be right-angled or rounded with a predetermined curvature. The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the embodiment of the disclosure is not limited thereto.

The display panel 100 includes a plurality of pixels PX, a plurality of scan lines SL, a plurality of emission control lines EL, a plurality of data lines DL, a scan driver 610, an emission driver 620, and a data driver 700. The display panel 100 may be divided into a display area DAA displaying an image and a non-display area NDA not displaying an image as shown in FIG. 2.

The plurality of pixels PX may be arranged in the display area DAA. The plurality of pixels PX may be arranged in a matrix form in the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL include a plurality of write scan lines GWL, a plurality of control scan lines GCL, and a plurality of bias scan lines GBL. The plurality of emission control lines EL include a plurality of first emission control lines ECL1 and a plurality of second emission control lines ECL2.

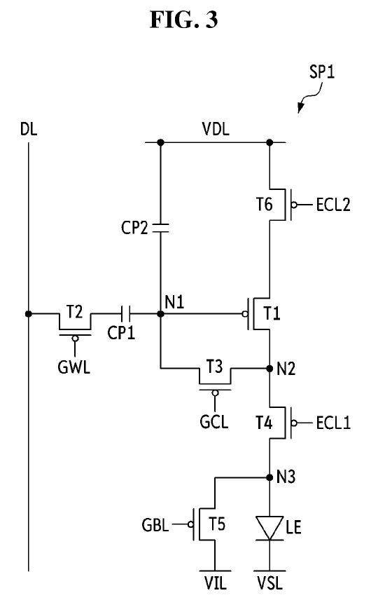

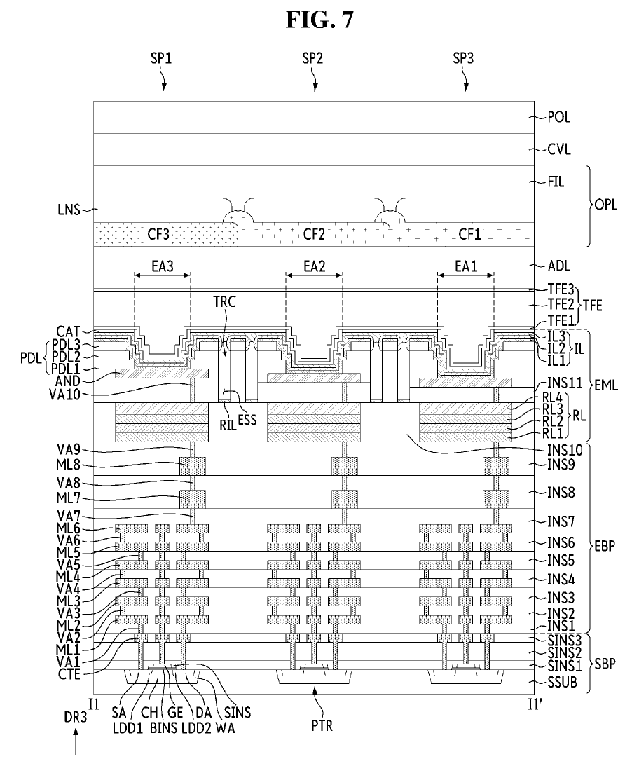

The plurality of pixels PX include a plurality of sub-pixels SP1, SP2, and SP3. The plurality of sub-pixels SP1, SP2, and SP3 may include a plurality of pixel transistors as shown in FIG. 3, and the plurality of pixel transistors may be formed by a semiconductor process and disposed on a semiconductor substrate SSUB (refer to FIG. 7). In an embodiment, the plurality of pixel transistors of the data driver 700 may be formed as complementary metal oxide semiconductor (“CMOS”) transistors, for example, but the embodiment of the disclosure is not limited thereto.

Each of the plurality of sub-pixels SP1, SP2, and SP3 may be connected to one write scan line GWL, one control scan line GCL, one bias scan line GBL, one first emission control line ECL1, one second emission control line ECL2, and one data line DL. Each of the plurality of sub-pixels SP1, SP2, and SP3 may receive a data voltage of the data line DL in response to a write scan signal of the write scan line GWL, and emit light from the light-emitting element according to the data voltage.

The scan driver 610, the emission driver 620, and the data driver 700 may be disposed in the non-display area NDA.

The scan driver 610 includes a plurality of scan transistors, and the emission driver 620 includes a plurality of light-emitting transistors. The plurality of scan transistors and the plurality of light-emitting transistors may be formed on the semiconductor substrate SSUB (refer to FIG. 7) through a semiconductor process. In an embodiment, the plurality of scan transistors and the plurality of light-emitting transistors may be formed as CMOS transistors, for example, but the embodiment of the disclosure is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to the bias scan lines GBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines ECL1. The second emission control driver 622 may generate second emission control signals according to the emission timing control signal ECS and sequentially output them to the second emission control lines ECL2.

The data driver 700 may include a plurality of data transistors, and the plurality of data transistors may be formed on the semiconductor substrate SSUB (refer to FIG. 7) through a semiconductor process. In an embodiment, the plurality of data transistors may be formed as CMOS transistors, for example, but the embodiment of the disclosure is not limited thereto.

The data driver 700 may receive digital video data DATA and a data timing control signal DCS from the timing control circuit 400. The data driver 700 converts the digital video data DATA into analog data voltages according to the data timing control signal DCS and outputs the analog data voltages to data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be disposed on one surface, e.g., the rear surface, of the display panel 100. The heat dissipation layer 200 serves to dissipate heat generated from the display panel 100. The heat dissipation layer 200 may include a metal layer having relatively high thermal conductivity, such as graphite, silver (Ag), copper (Cu), or aluminum (Al).

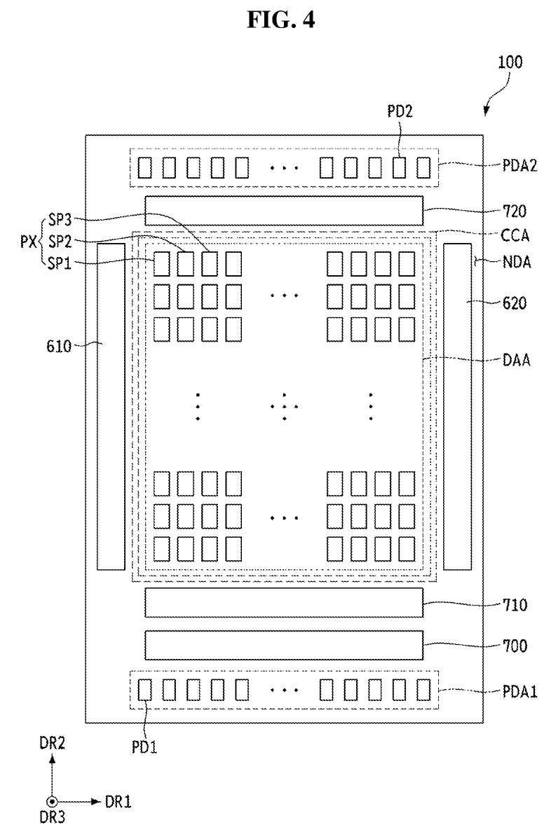

The circuit board 300 may be electrically connected to a plurality of first pads PD1 (refer to FIG. 4) of a first pad portion PDA1 (refer to FIG. 4) of the display panel 100 by a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, one end of the circuit board 300 may be disposed on the rear surface of the display panel 100 and/or the rear surface of the heat dissipation layer 200. An opposite end of the circuit board 300 may be connected to the plurality of first pads PD1 (refer to FIG. 4) of the first pad portion PDA1 (refer to FIG. 4) of the display panel 100 by a conductive adhesive member. One end of the circuit board 300 may be an opposite end of an opposite end of the circuit board 300.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. In an embodiment, the power supply circuit 500 may generate a first driving voltage VSS, a second driving voltage VDD, and a third driving voltage VINT and supply them to the display panel 100, for example. The first driving voltage VSS, the second driving voltage VDD, and the third driving voltage VINT will be described later in conjunction with FIG. 3

Each of the timing control circuit 400 and the power supply circuit 500 may be formed as an integrated circuit (“IC”) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

In an alternative embodiment, each of the timing control circuit 400 and the power supply circuit 500 may be disposed in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed on the semiconductor substrate SSUB (refer to FIG. 7) through a semiconductor process. In an embodiment, the plurality of timing transistors and the plurality of power transistors may be formed as CMOS transistors, for example, but the embodiment of the disclosure is not limited thereto. Each of the timing control circuit 400 and the power supply circuit 500 may be disposed between the data driver 700 and the first pad portion PDA1 (refer to FIG. 4).

FIG. 3 is an equivalent circuit diagram showing an embodiment of a first sub-pixel shown in FIG. 2.

Referring to FIG. 3, the first sub-pixel SP1 may be connected to the write scan line GWL, the control scan line GCL, the bias scan line GBL, the first emission control line ECL1, the second emission control line ECL2, and the data line DL. Further, the first sub-pixel SP1 may be connected to a first driving voltage line VSL to which the first driving voltage VSS corresponding to a relatively low potential voltage is applied, a second driving voltage line VDL to which the second driving voltage VDD corresponding to a relatively high potential voltage is applied, and a third driving voltage line VIL to which the third driving voltage VINT corresponding to an initialization voltage is applied.

The first sub-pixel SP1 includes a plurality of transistors T1 to T6, a light-emitting element LE, a first capacitor CP1, and a second capacitor CP2.

The light-emitting element LE emits light in response to a driving current Ids flowing through the channel of the first transistor T1. The emission amount of the light-emitting element LE may be proportional to the driving current Ids. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer disposed between the first electrode and the second electrode, but the embodiment of the disclosure is not limited thereto. In an embodiment, the light-emitting element LE may be an inorganic light-emitting element including a first electrode, a second electrode, and an inorganic semiconductor disposed between the first electrode and the second electrode, in which case the light-emitting element LE may be a micro light-emitting diode, for example.

The first transistor T1 may be a driving transistor that controls a source-drain current Ids (hereinafter referred to as “driving current”) flowing between the source electrode and the drain electrode according to a voltage applied to the gate electrode.

A second transistor T2 may be disposed between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1.

A third transistor T3 may be disposed between a first node N1 and a second node N2. The third transistor T3 is turned on by the write control signal of the write control line GCL to connect the first node N1 to the second node N2. For this reason, when the gate electrode and the source electrode of the first transistor T1 are connected, the first transistor T1 may operate like a diode.

The fourth transistor T4 may be connected between the second node N2 and a third node N3. The fourth transistor T4 is turned on by the first emission control signal of the first emission control line ECL1 to connect the second node N2 to the third node N3. Accordingly, the driving current of the first transistor T1 may be supplied to the light-emitting element LE. A fifth transistor T5 may be disposed between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light-emitting element LE.

The sixth transistor T6 may be disposed between the source electrode of the first transistor T1 and the second driving voltage line VDL. The sixth transistor T6 is turned on by the second emission control signal of the second emission control line ECL2 to connect the source electrode of the first transistor T1 to the second driving voltage line VDL. Accordingly, the second driving voltage VDD of the second driving voltage line VDL may be applied to the source electrode of the first transistor T1.

The first capacitor CP1 is formed between the first node N1 and the drain electrode of the second transistor T2. The second capacitor CP2 is formed between the gate electrode of the first transistor T1 and the second driving voltage line VDL.

Each of the first to sixth transistors T1 to T6 may be a metal-oxide-semiconductor field effect transistor (“MOSFET”). In an embodiment, each of the first to sixth transistors T1 to T6 may be a p-type MOSFET, for example, but the embodiment of the disclosure is not limited thereto. Each of the first to sixth transistors T1 to T6 may be an n-type MOSFET. In an alternative embodiment, some of the first to sixth transistors T1 to T6 may be p-type MOSFETs, and each of the remaining transistors may be an n-type MOSFET.

Although it is illustrated in FIG. 3 that the first sub-pixel SP1 includes six transistors T1 to T6 and two capacitors CP1 and CP2, it should be noted that the equivalent circuit diagram of the first sub-pixel SP1 is not limited to that shown in FIG. 3. In an embodiment, the number of transistors and the number of capacitors of the first sub-pixel SP1 are not limited to those shown in FIG. 3, for example.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 is not repeated in the disclosure.

FIG. 4 is a schematic plan view illustrating an embodiment of the display panel shown in FIG. 1.

Referring to FIG. 4, the display area DAA of the display panel 100 in an embodiment includes the plurality of pixels PX arranged in a matrix form. The non-display area NDA of the display panel 100 in an embodiment includes the scan driver 610, the emission driver 620, the data driver 700, a first distribution circuit 710, a second distribution circuit 720, the first pad portion PDA1, and a second pad portion PDA2.

The scan driver 610 may be disposed on a first side of the display area DAA, and the emission driver 620 may be disposed on a second side of the display area DAA. In an embodiment, the scan driver 610 may be disposed on one side of the display area DAA in the first direction DR1, and the emission driver 620 may be disposed on an opposite side of the display area DAA in the first direction DR1, for example. However, the embodiment of the disclosure is not limited thereto, and the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on a third side of the display area DAA. In an embodiment, the first pad portion PDA1 may be disposed on one side of the display area DAA in the second direction DR2, for example. The first pad portion PDA1 may be disposed outside the data driver 700 in the second direction DR2.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board including a rigid material or a flexible printed circuit board including a flexible material.

The second pad portion PDA2 may be disposed on a fourth side of the display area DAA. In an embodiment, the second pad portion PDA2 may be disposed on an opposite side of the display area DAA in the second direction DR2, for example. The second pad portion PDA2 may be disposed outside the second distribution circuit 720 in the second direction DR2.

The first distribution circuit 710 distributes data voltages applied through the first pad portion PDA1 to the plurality of data lines DL. In an embodiment, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced, for example. The first distribution circuit 710 may be disposed on the third side of the display area DAA of the display panel 100. In an embodiment, the first distribution circuit 710 may be disposed on one side of the display area DAA in the second direction DR2, for example.

The second distribution circuit 720 distributes signals applied through the second pad portion PDA2 to the scan driver 610, the emission driver 620, and the data lines DL. The second pad portion PDA2 and the second distribution circuit 720 may inspect the operation of each of the pixels PX in the display area DAA. The second distribution circuit 720 may be disposed on the fourth side of the display area DAA of the display panel 100. In an embodiment, the second distribution circuit 720 may be disposed on an opposite side of the display area DAA in the second direction DR2, for example.

A cathode connection portion CCA may be a region in which a second electrode CAT (refer to FIG. 7) of a display element layer EML (refer to FIG. 7) is connected to the first driving voltage line VSL of the non-display area NDA. The cathode connection portion CCA may be disposed outside at least one side of the display area DAA. In an embodiment, the cathode connection portion CCA may be disposed outside at least on one side among the left side, the right side, the upper side, and the lower side of the display area DAA, for example. In an alternative embodiment, the cathode connection portion CCA may be disposed to surround the display area DAA as shown in FIG. 4 in order to minimize a deviation in the first driving voltage VSS due to a voltage drop (IR drop) or voltage rise (IR rising) of the second electrode CAT in the display area DAA.

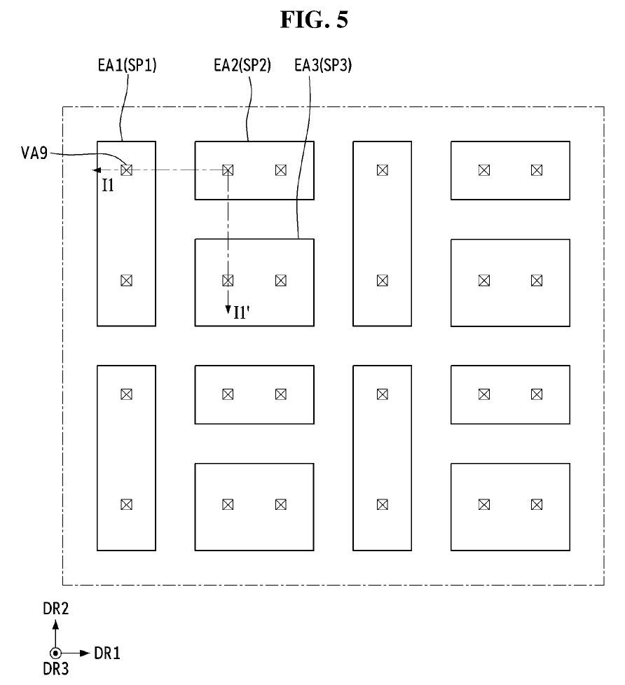

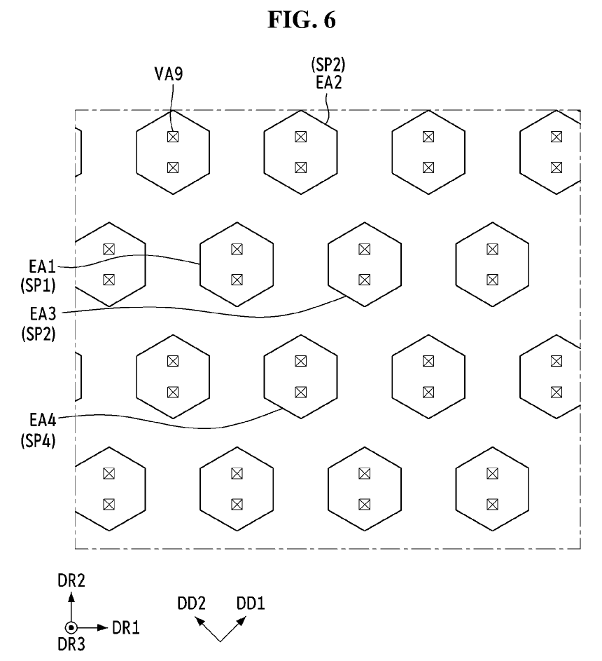

FIG. 5 is a schematic enlarged plan view showing an embodiment of the display area of FIG. 4. FIG. 6 is a schematic enlarged plan view showing another embodiment of the display area of FIG. 4.

Referring to FIGS. 5 and 6, each of the pixels PX includes a first emission area EA1 that is an emission area of the first sub-pixel SP1, a second emission area EA2 that is an emission area of the second sub-pixel SP2, and a third emission area EA3 that is an emission area of the third sub-pixel SP3.

The first emission area EA1, the second emission area EA2, and the third emission area EA3 may have, in a plan view, a quadrilateral or hexagonal shape as shown in FIGS. 5 and 6, but the disclosure is not limited thereto. The first emission area EA1, the second emission area EA2, and the third emission area EA3 may have a polygonal shape other than a quadrangle or hexagon, a circular shape, an elliptical shape, or an atypical shape in a plan view.

As shown in FIG. 5, in each of the plurality of pixels PX, the first emission area EA1 and the second emission area EA2 may be next (adjacent) to each other in the first direction DR1. Further, the first emission area EA1 and the third emission area EA3 may be next (adjacent) to each other in the first direction DR1. In addition, the second emission area EA2 and the third emission area EA3 may be next (adjacent) to each other in the second direction DR2. The area of the first emission area EA1, the area of the second emission area EA2, and the area of the third emission area EA3 may be different.

In an alternative embodiment, as shown in FIG. 6, the emission areas EA1, EA2, EA3, and EA4 may have a hexagonal shape in a plan view. In this case, the first emission area EA1 and the third emission area EA3 may be next (adjacent) to each other in the first direction DR1, and the second emission area EA2 and the fourth emission area EA4 may be next (adjacent) to each other in the second direction DR2. Additionally, the first emission area EA1 and the second emission area EA2 may be next (adjacent) to each other in a first diagonal direction DD1, and the second emission area EA2 and the third emission area EA3 may be next (adjacent) to each other in a second diagonal direction DD2. Additionally, the first emission area EA1 and the fourth emission area EA4 may be next (adjacent) to each other in the second diagonal direction DD2, and the third emission area EA3 and the fourth emission area EA4 may be next (adjacent) to each other in the first diagonal direction DD1. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first sub-pixel SP1 may emit first light, the second sub-pixel SP2 may emit second light, and the third sub-pixel SP3 may emit third light. Here, the first light may be light of a blue wavelength band, the second light may be light of a green wavelength band, and the third light may be light of a red wavelength band. In an embodiment, the blue wavelength band may be a wavelength band of light whose main peak wavelength is in the range of approximately 370 nanometers (nm) to approximately 460 nm, the green wavelength band may be a wavelength band of light whose main peak wavelength is in the range of approximately 480 nm to approximately 560 nm, and the red wavelength band may be a wavelength band of light whose main peak wavelength is in the range of approximately 600 nm to approximately 750 nm, for example.

Each of the plurality of pixels PX may include three emission areas EA1, EA2, and EA3 as shown in FIG. 5, or may include four emission areas EA1, EA2, EA3, and EA4 as shown in FIG. 6. In this case, the fourth emission area EA4 may emit the same second light as the second emission area EA2, but the disclosure is not limited thereto.

The emission areas of the plurality of pixels PX may be arranged in a stripe structure in which the emission areas are arranged in the first direction DR1, a PenTile® structure in which the emission areas EA1, EA2, EA3, and EA4 are arranged in a rhombus shape, or a hexagonal structure in which the emission areas each having a hexagonal shape are arranged as shown in FIG. 6.

FIG. 7 is a schematic cross-sectional view illustrating an embodiment of a display panel taken along line I1-I1’of FIG. 5.

Referring to FIG. 7, the display panel 100 includes a semiconductor backplane SBP, a light-emitting element backplane EBP, the display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 3.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the aforementioned first type impurity. In an embodiment, when the first type impurity is a p-type impurity, the second type impurity may be an n-type impurity, for example. In an alternative embodiment, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3, which is the thickness direction of the semiconductor substrate SSUB. The channel region CH may overlap the gate electrode GE in the third direction DR3. The source region SA may be disposed on one side of the gate electrode GE, and the drain region DA may be disposed on an opposite side of the gate electrode GE.

Each of the plurality of well regions WA further includes a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the first low-concentration impurity region LDD1 and the second low-concentration impurity region LDD2, which may result in an increase of the length of the channel region CH of each of the pixel transistors PTR.

A first semiconductor insulating film SINS1 may be disposed on the semiconductor substrate SSUB. A second semiconductor insulating film SINS2 may be disposed on the first semiconductor insulating film SINS1.

The plurality of contact terminals CTE may be disposed on the second semiconductor insulating film SINS2. Each of the plurality of contact terminals CTE may be connected to any one of the gate electrode GE, the source region SA, and the drain region DA of each of the pixel transistors PTR through a hole penetrating the first semiconductor insulating film SINS1 and the second semiconductor insulating film SINS2. The plurality of contact terminals CTE may include any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating film SINS3 may be disposed on a side surface of each of the plurality of contact terminals CTE. The top surface of each of the plurality of contact terminals CTE may be exposed without being covered by the third semiconductor insulating film SINS3.

Each of the first semiconductor insulating film SINS1, the second semiconductor insulating film SINS2, and the third semiconductor insulating film SINS3 may be formed as a silicon carbonitride (SiCN) or silicon oxide (SiOₓ)-based inorganic film, but the disclosure is not limited thereto.

The semiconductor substrate SSUB may be replaced with a glass substrate or a polymer resin substrate such as polyimide. In this case, thin film transistors may be disposed on the glass substrate or the polymer resin substrate. The glass substrate may be a rigid substrate that does not bend, and the polymer resin substrate may be a flexible substrate that may be bent or curved.

The light-emitting element backplane EBP includes a plurality of conductive layers ML1 to ML8, a plurality of vias VA1 to VA9, and a plurality of insulating films INS1 to INS9. In addition, the light-emitting element backplane EBP includes a plurality of insulating films INS1 to INS9 disposed between first to eighth conductive layers ML1 to ML8.

First to eighth insulating films INS1 to INS8 serve to insulate the first to eighth conductive layers ML1 to ML8. The first to eighth conductive layers ML1 to ML8 serve to connect the plurality of contact terminals CTE exposed from the semiconductor backplane SBP to thereby implement the circuit of the first sub-pixel SP1 shown in FIG. 3.

In an embodiment, the first to sixth transistors T1 to T6 are merely formed in the semiconductor backplane SBP, and the connection of the first to sixth transistors T1 to T6 and the first and second capacitors CP1 and CP2 is accomplished through the first to eighth conductive layers ML1 to ML8, for example. In addition, the connection between the drain region corresponding to the drain electrode of the fourth transistor T4, the source region corresponding to the source electrode of the fifth transistor T5, and a first electrode AND of the light-emitting element LE is also accomplished through the first to eighth conductive layers ML1 to ML8.

The first to eighth conductive layers ML1 to ML8 and the first to eighth vias VA1 to VA8 may include substantially the same material as each other. The first to eighth conductive layers ML1 to ML8 and the first to eighth vias VA1 to VA8 may include any one of copper (Cu), aluminum (Al), tungsten (W), molybdenum (Mo), chromium (Cr), gold (Au), titanium (Ti), nickel (Ni), and neodymium (Nd), or an alloy including any one of them. The first to eighth vias VA1 to VA8 may include substantially the same material as each other. The first to eighth insulating films INS1 to INS8 may be formed as silicon oxide (SiOₓ)-based inorganic films, but the embodiment of the disclosure is not limited thereto.

A ninth insulating film INS9 may be disposed on the eighth insulating film INS8 and the eighth conductive layer ML8. The ninth insulating film INS9 may be formed as a silicon oxide (SiOₓ)-based inorganic film, but the embodiment of the disclosure is not limited thereto.

Each of the ninth vias VA9 may penetrate the ninth insulating film INS9 and be connected to the exposed eighth conductive layer ML8. The ninth vias VA9 may include any one of copper (Cu), aluminum (Al), tungsten (W), molybdenum (Mo), chromium (Cr), gold (Au), titanium (Ti), nickel (Ni), and neodymium (Nd), or an alloy including any one of them.

The display element layer EML may be disposed on the light-emitting element backplane EBP. The display element layer EML may include tenth and eleventh insulating films INS10 and INS11, a reflective electrode RL, the first electrodes AND, a light-emitting stack IL, the second electrode CAT, and a pixel defining film PDL, and a plurality of trenches TRC may be defined in the display element layer EML.

The reflective electrode RL may be disposed on the ninth insulating film INS9. The reflective electrode RL may include at least one reflective electrode RL1, RL2, RL3, and RL4. In an embodiment, the reflective electrode RL may include first to fourth reflective electrodes RL1, RL2, RL3, and RL4 as shown in FIG. 7, for example.

The first reflective electrodes RL1 may be disposed on the ninth insulating film INS9, and may be connected to the ninth via VA9. Each of the second reflective electrodes RL2 may be disposed on the first reflective electrode RL1 corresponding thereto. Each of the third reflective electrodes RL3 may be disposed on the second reflective electrode RL2 corresponding thereto. Each of the fourth reflective electrodes RL4 may be disposed on the third reflective electrode RL3 corresponding thereto.

Since the second reflective electrode RL2 is an electrode that substantially reflects light from the light-emitting elements LE, the thickness of the second reflective electrode RL2 may be greater than the thickness of each of the first reflective electrode RL1, the third reflective electrode RL3, and the fourth reflective electrode RL4.

The first reflective electrodes RL1 may include any one of copper (Cu), aluminum (Al), tungsten (W), molybdenum (Mo), chromium (Cr), gold (Au), titanium (Ti), nickel (Ni), and neodymium (Nd), or an alloy including any one of them. In an embodiment, the first reflective electrodes RL1 may include titanium nitride (TiN), the second reflective electrodes RL2 may include aluminum (Al), the third reflective electrodes RL3 may include titanium nitride (TiN), and the fourth reflective electrodes RL4 may include titanium (Ti), for example.

The tenth insulating film INS10 may be disposed between the reflective electrodes RL next (adjacent) to each other. The tenth insulating film INS10 may be a film for flattening a stepped portion caused by the reflective electrodes RL. The eleventh insulating film INS11 may be disposed on the tenth insulating film INS10 and a reflective electrode RL.

The tenth insulating film INS10 and the eleventh insulating film INS11 may be formed as silicon oxide (SiOₓ)-based inorganic films, but the embodiment of the disclosure is not limited thereto.

The eleventh insulating film INS11 may be an optical auxiliary layer for adjusting the resonance distance of light emitted from the light-emitting stack IL in at least one of the first sub-pixel SP1, the second sub-pixel SP2, or the third sub-pixel SP3. The thickness of the eleventh insulating film INS11 may be different in the first sub-pixel SP1, the second sub-pixel SP2, and the third sub-pixel SP3. That is, in order to adjust a distance from the reflective electrode RL to the second electrode CAT according to a main wavelength of light emitted from each of the first sub-pixel SP1, the second sub-pixel SP2, and the third sub-pixel SP3, the thickness of the eleventh insulating film INS11 may be set for each of the first sub-pixel SP1, the second sub-pixel SP2, and the third sub-pixel SP3.

In an embodiment, as shown in FIG. 7, the thickness of the eleventh insulating film INS11 in the first sub-pixel SP1 may be greater than the thickness of the eleventh insulating film INS11 in the second sub-pixel SP2, and the thickness of the eleventh insulating film INS11 in the second sub-pixel SP2 may be greater than the thickness of the eleventh insulating film INS11 in the third sub-pixel SP3, for example. In this case, the distance between the first electrode AND and the reflective electrode RL in the first sub-pixel SP1 is greater than the distance between the first electrode AND and the reflective electrode RL in the second sub-pixel SP2. In addition, the distance between the first electrode AND and the reflective electrode RL in the second sub-pixel SP2 is greater than the distance between the first electrode AND and the reflective electrode RL in the third sub-pixel SP3.

Each of the tenth vias VA10 may penetrate the eleventh insulating film INS11 and be connected to the exposed fourth reflective electrode RL4. The tenth vias VA10 may include any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the tenth via VA10 in the first sub-pixel SP1 may be greater than the thickness of the tenth via VA10 in the second sub-pixel SP2, and the thickness of the tenth via VA10 in the second sub-pixel SP2 may be greater than the thickness of the tenth via VA10 in the third sub-pixel SP3.

The first electrode AND of each of the light-emitting elements LE may be disposed on the eleventh insulating film INS11 and connected to the tenth via VA10. The first electrode AND of each of the light-emitting elements LE may be connected to the drain region DA or source region SA of the pixel transistor PTR through the tenth via VA10, the reflective electrode RL, the first to ninth vias VA1 to VA9, the first to eighth conductive layers (e.g., first to eighth metal layers) ML1 to ML8, and the contact terminal CTE. The first electrode AND of each of the light-emitting elements LE may include any one of copper (Cu), aluminum (Al), tungsten (W), molybdenum (Mo), chromium (Cr), gold (Au), titanium (Ti), nickel (Ni), and neodymium (Nd), or an alloy including any one of them. In an embodiment, the first electrode AND of each of the light-emitting elements LE may be titanium nitride (TiN), for example.

The pixel defining film PDL may be disposed on a part of the first electrode AND of each of the light-emitting elements LE. The pixel defining film PDL may cover the edge of the first electrode AND of each of the light-emitting elements LE. The pixel defining film PDL may partition the first emission areas EA1, the second emission areas EA2, and the third emission areas EA3. Each of the first emission area EA1, the second emission area EA2, and the third emission area EA3 may be an area where the light-emitting element LE including the first electrode AND, the light-emitting stack IL, and the second electrode CAT is disposed.

The first emission area EA1 may be defined as an area in which the first electrode AND, the light-emitting stack IL, and the second electrode CAT are sequentially stacked in the first sub-pixel SP1 to emit light. The second emission area EA2 may be defined as an area in which the first electrode AND, the light-emitting stack IL, and the second electrode CAT are sequentially stacked in the second sub-pixel SP2 to emit light. The third emission area EA3 may be defined as an area in which the first electrode AND, the light-emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the edge of the first electrode AND of each of the light-emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed as silicon oxide (SiOₓ)-based inorganic films. In an alternative embodiment, the first pixel defining film PDL1 and the third pixel defining film PDL3 may be formed as silicon nitride (SiNₓ)-based inorganic films, whereas the second pixel defining film PDL2 may be formed as a silicon oxide (SiOₓ)-based inorganic film. The first pixel defining film PDL1, the second pixel defining film PDL2, and the third pixel defining film PDL3 may each have a thickness of about 500 angstroms (Å).

In order to reduce or prevent the likelihood of a first encapsulation inorganic film TFE1 being cut off due to the step coverage, the first pixel defining film PDL1, the second pixel defining film PDL2, and the third pixel defining film PDL3 may have a cross-sectional structure having a stepped portion. Step coverage refers to the ratio of the degree of thin film coated on an inclined portion to the degree of thin film coated on a flat portion. The lower the step coverage, the more likely it is that the thin film will be cut off at inclined portions.

Each of the plurality of trenches TRC may penetrate the first pixel defining film PDL1, the second pixel defining film PDL2, and the third pixel defining film PDL3. The eleventh insulating film INS11 may be partially recessed at each of the plurality of trenches TRC.

At least one trench TRC may be disposed between the neighboring sub-pixels SP1, SP2, and SP3. Although FIG. 7 illustrates that two trenches TRC are disposed between the neighboring sub-pixels SP1, SP2, and SP3, the disclosure is not limited thereto.

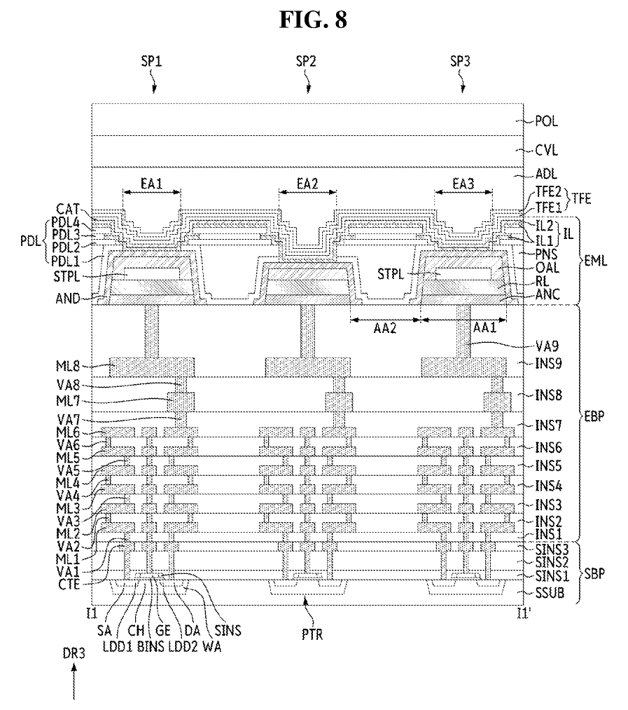

The light-emitting stack IL may include a plurality of stack layers IL1, IL2, and IL3. FIG. 7 illustrates that the light-emitting stack IL has a three-tandem structure including a first stack layer IL1, a second stack layer IL2, and a third stack layer IL3, but the disclosure is not limited thereto. In an embodiment, the light-emitting stack IL may have a two-tandem structure including two stack layers as shown in FIG. 8, for example.

In the three-tandem structure, the light-emitting stack IL may have a tandem structure including a plurality of stack layers IL1, IL2, and IL3 that emit different lights. In an embodiment, the light-emitting stack IL may include the first stack layer IL1 that emits first light, the second stack layer IL2 that emits second light, and the third stack layer IL3 that emits third light, for example. The first stack layer IL1, the second stack layer IL2, and the third stack layer IL3 may be sequentially stacked.

The first stack layer IL1 may have a structure in which a first hole transport layer, a first light-emitting layer that emits the first light, and a first electron transport layer are sequentially stacked. The second stack layer IL2 may have a structure in which a second hole transport layer, a second light-emitting layer that emits the second light, and a second electron transport layer are sequentially stacked. The third stack layer IL3 may have a structure in which a third hole transport layer, a third light-emitting layer that emits the third light, and a third electron transport layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an n-type charge generation layer that supplies electrons to the first stack layer IL1 and a p-type charge generation layer that supplies holes to the second stack layer IL2. The n-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an n-type charge generation layer that supplies electrons to the second stack layer IL2 and a p-type charge generation layer that supplies holes to the third stack layer IL3.

The first stack layer IL1 may be disposed on the first electrodes AND and the pixel defining film PDL, and a residual film RIL disposed on the bottom surface (also referred to as a lower surface) of each trench TRC may be the same material as that of the first stack layer IL1. Due to the trench TRC, the first stack layer IL1 may be cut off between the neighboring sub-pixels SP1, SP2, and SP3. The second stack layer IL2 may be disposed on the first stack layer IL1. Due to the trench TRC, the second stack layer IL2 may be cut off between the neighboring sub-pixels SP1, SP2, and SP3. A cavity ESS or an empty space may be disposed between the residual film RIL and the second stack layer IL2 in the trench TRC. The third stack layer IL3 may be disposed on the second stack layer IL2. The third stack layer IL3 is not cut off by the trench TRC and may be disposed to cover the second stack layer IL2 in each of the trenches TRC.

In the three-tandem structure, each of the plurality of trenches TRC may be a structure for cutting off the first to third hole transport layers, the first charge generation layer, and the second charge generation layer of the first to third stack layers IL1, IL2, and IL3 of the display element layer EML between the neighboring sub-pixels SP1, SP2, and SP3. In addition, in the two-tandem structure, each of the plurality of trenches TRC may be a structure for cutting off the charge generation layer and the lower stack layer disposed between the lower stack layer and the upper stack layer.

In order to stably cut off the first and second stack layers IL1 and IL2 of the display element layer EML between the neighboring sub-pixels SP1, SP2, and SP3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the charge generation layers and the hole transport layers of the light-emitting stack IL of the display element layer EML between the neighboring sub-pixels SP1, SP2, and SP3, another structure may exist instead of the trench TRC. In an embodiment, instead of the trench TRC, a reverse tapered partition wall may be disposed on the pixel defining film PDL, for example.

In addition, FIG. 7 illustrates that the light-emitting stack IL that emits light is disposed in the first emission area EA1, the second emission area EA2, and the third emission area EA3, but the disclosure is not limited thereto. In an embodiment, instead of the light-emitting stack IL, the first light-emitting layer may be disposed in the first emission area EA1, and may be omitted from the second emission area EA2 and the third emission area EA3, for example. Furthermore, the second light-emitting layer may be disposed in the second emission area EA2 and may be omitted from the first emission area EA1 and the third emission area EA3. Furthermore, the third light-emitting layer may be disposed in the third emission area EA3 and may be omitted from the first emission area EA1 and the second emission area EA2. In this case, first to third color filters CF1, CF2, and CF3 of the optical layer OPL may be omitted.

The second electrode CAT may be disposed on the light-emitting stack IL. The second electrode CAT may be disposed on the third stack layer IL3 in each of the plurality of trenches TRC. The second electrode CAT may include a transparent conductive material (“TCO”) such as indium tin oxide (“ITO”) or indium zinc oxide (“IZO”) that may transmit light or a semi-transmissive conductive material such as magnesium (Mg), silver (Ag), or an alloy of Mg and Ag. When the second electrode CAT includes a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic film TFE1 and TFE3 to prevent oxygen or moisture from permeating into the display element layer EML. In an embodiment, the first encapsulation inorganic film TFE1 may be disposed on the second electrode CAT, and a second encapsulation inorganic film TFE3 may be disposed above the first encapsulation inorganic film TFE1, for example. The first encapsulation inorganic film TFE1 and the second encapsulation inorganic film TFE3 may be formed as multiple films in which one or more inorganic films of silicon nitride (SiNₓ), silicon oxynitride (SiON), silicon oxide (SiOₓ), titanium oxide (TiOₓ), and aluminum oxide (AlOₓ) are alternately stacked.

In addition, the encapsulation layer TFE may include at least one organic film TFE2 to protect the display element layer EML from foreign substances such as dust. In an embodiment, the organic film (hereinafter, also referred to as an encapsulation organic film) TFE2 may be disposed between the first encapsulation inorganic film TFE1 and the second encapsulation inorganic film TFE3, for example. The encapsulation organic film TFE2 may be a monomer. In an alternative embodiment, the encapsulation organic film TFE2 may be an organic film such as acryl resin, epoxy resin, phenolic resin, polyamide resin, polyimide resin or the like.

An adhesive layer ADL may be a layer for bonding the encapsulation layer TFE to the optical layer OPL. The adhesive layer ADL may be a double-sided adhesive member. In addition, the adhesive layer ADL may be a transparent adhesive member such as a transparent adhesive or a transparent adhesive resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be disposed on the adhesive layer ADL.

The first color filter CF1 may overlap the first emission area EA1 of the first sub-pixel SP1. The first color filter CF1 may transmit light of the first color, i.e., light of a blue wavelength band. The blue wavelength band may be about 370 nm to about 460 nm. Thus, the first color filter CF1 may transmit light of the first color among light emitted from the first emission area EA1.

The second color filter CF2 may overlap the second emission area EA2 of the second sub-pixel SP2. The second color filter CF2 may transmit light of the second color, i.e., light of a green wavelength band. The green wavelength band may be about 480 nm to about 560 nm. Thus, the second color filter CF2 may transmit light of the second color among light emitted from the second emission area EA2.

The third color filter CF3 may overlap the third emission area EA3 of the third sub-pixel SP3. The third color filter CF3 may transmit light of the third color, i.e., light of a red wavelength band. The red wavelength band may be about 600 nm to about 750 nm. Thus, the third color filter CF3 may transmit light of the third color among light emitted from the third emission area EA3.

The plurality of lenses LNS may be disposed on the first color filter CF1, the second color filter CF2, and the third color filter CF3, respectively. Each of the plurality of lenses LNS may be a structure for increasing the proportion of light directed to the front of the display device 10. Each of the plurality of lenses LNS may have a cross-sectional shape that is convex in an upward direction.

The filling layer FIL may be disposed on the plurality of lenses LNS. The filling layer FIL may have a predetermined refractive index such that light travels in the third direction DR3 at an interface between the filling layer FIL and the plurality of lenses LNS. Further, the filling layer FIL may be a planarization layer. The filling layer FIL may be an organic film such as acrylic resin, epoxy resin, phenolic resin, polyamide resin, or polyimide resin.

The cover layer CVL may be disposed on the filling layer FIL. The cover layer CVL may be a glass substrate or a polymer resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

The polarizing plate may be disposed on one surface of the cover layer CVL. The polarizing plate may be a structure for reducing or preventing visibility degradation caused by reflection of external light. The polarizing plate may include a linear polarizing plate and a phase retardation film. In an embodiment, the phase retardation film may be a λ/4 plate (quarter-wave plate), for example, but the embodiment of the disclosure is not limited thereto. However, when visibility degradation caused by reflection of external light is sufficiently overcome by the first to third color filters CF1, CF2, and CF3, the polarizing plate may be omitted.

FIG. 8 is a schematic cross-sectional view illustrating another embodiment of a display panel taken along line I1-I1’of FIG. 5.

The embodiment of FIG. 8 differs from the embodiment of FIG. 7 in that the first electrode AND of each of the light-emitting elements LE contacts and electrically connected to the side surface of a connection electrode ANC connected to the eighth conductive layer ML8. The embodiment of FIG. 8 also differs from the embodiment of FIG. 7 in that the trench TRC is omitted, and instead, the third pixel defining film PDL3 and a fourth pixel defining film PDL4 have an eaves-shaped or mushroom-shaped cross-sectional structure. In the embodiment of FIG. 8, redundant description of parts already described in the embodiment of FIG. 7 will be omitted.

Referring to FIG. 8, the plurality of connection electrodes ANC may be respectively disposed on first portions AA1 of the ninth insulating film INS9. Each of the plurality of connection electrodes ANC may be disposed on the first portion AA1 of the ninth insulating film INS9 corresponding thereto. A plurality of connection electrodes ANC may include any one of copper (Cu), aluminum (Al), tungsten (W), molybdenum (Mo), chromium (Cr), gold (Au), titanium (Ti), nickel (Ni), and neodymium (Nd), an alloy including any one of them, or a transparent conductive oxide. In an embodiment, the plurality of connection electrodes ANC may include titanium (Ti), titanium nitride (TiN), indium tin oxide (“ITO”), or indium zinc oxide (“IZO”), for example, but the disclosure is limited thereto.

A plurality of reflective electrodes RL may be respectively disposed on the plurality of connection electrodes ANC. Each of the plurality of reflective electrodes RL may be disposed on the connection electrode ANC corresponding thereto. The plurality of reflective electrodes RL may include any one of copper (Cu), aluminum (Al), tungsten (W), molybdenum (Mo), chromium (Cr), gold (Au), titanium (Ti), nickel (Ni), and neodymium (Nd), or an alloy including any one of them. In an embodiment, each of the plurality of reflective electrodes RL may include aluminum (Al) having relatively high reflectivity, for example.

A plurality of optical auxiliary films OAL may be respectively disposed on the plurality of reflective electrodes RL. Each of the plurality of optical auxiliary films OAL may be disposed on the reflective electrode RL corresponding thereto. The plurality of optical auxiliary films OAL may be formed as silicon oxide (SiOₓ)-based inorganic films, but the disclosure is not limited thereto.

In each of the first emission area EA1 and the third emission area EA3, a step layer STPL may be disposed on the reflective electrode RL, and the optical auxiliary film OAL may be disposed on the step layer STPL. In the second emission area EA2, only the optical auxiliary film OAL may be disposed on the reflective electrode RL. The thicknesses of the optical auxiliary film OAL may be substantially the same in the first emission area EA1, the second emission area EA2, and the third emission area EA3.

Due to the step layer STPL, the distance between the reflective electrode RL and the first electrode AND in the first emission area EA1 and the third emission area EA3 may be greater than the distance between the reflective electrode RL and the first electrode AND in the second emission area EA2. The thickness of the step layer STPL and the thickness of the optical auxiliary film OAL may be set in consideration of the wavelength and resonance distance of light emitted from the first stack layer IL1 of the light-emitting stack IL, and the wavelength and resonance distance of light emitted from the second stack layer IL2.

Each of the light-emitting elements LE may include the first electrode AND, the light-emitting stack IL, and the second electrode CAT.

The first electrode AND of each of the light-emitting elements LE may be disposed on the optical auxiliary film OAL corresponding thereto. Since the connection electrode ANC, the reflective electrode RL, and the optical auxiliary film OAL are sequentially stacked, the first electrode AND of each of the light-emitting elements LE may be disposed on the top surface and the side surface of the optical auxiliary film OAL, the side surface of the reflective electrode RL, and the side surface of the connection electrode ANC. Accordingly, the first electrode AND of each of the light-emitting elements LE may contact and electrically connected to the side surface of the reflective electrode RL and the side surface of the connection electrode ANC. Therefore, compared to when the first electrode AND of each of the light-emitting elements LE is connected to the reflective electrode RL exposed through a through hole penetrating the optical auxiliary film OAL, the number of mask processes may be reduced, thereby advantageously lowering manufacturing cost and increasing manufacturing efficiency.

The first electrode AND of each of the light-emitting elements LE may be connected to the drain region DA or the source region SA of the pixel transistor PTR through the connection electrode ANC, the first to ninth vias VA1 to VA9, the first to eighth conductive layers ML1 to ML8, and the contact terminal CTE.

The ninth insulating film INS9 may include the first portion AA1 that overlaps the connection electrode ANC in the third direction DR3 and a second portion AA2 that does not overlap the connection electrode ANC in the third direction DR3. The thickness of the first portion AA1 and the thickness of the second portion AA2 of the ninth insulating film INS9 may be substantially the same.

In an alternative embodiment, the thickness of the first portion AA1 of the ninth insulating film INS9 may be greater than the thickness of the second portion AA2. In this case, the side surface of the first portion AA1 of the ninth insulating film INS9 may be exposed, and the first electrode AND of each of the light-emitting elements LE may be disposed on the exposed side surface of the first portion AA1 of the ninth insulating film INS9.

The first electrode AND of each of the light-emitting elements LE may include any one of copper (Cu), aluminum (Al), tungsten (W), molybdenum (Mo), chromium (Cr), gold (Au), titanium (Ti), nickel (Ni), and neodymium (Nd), an alloy including any one of them, or a transparent conductive oxide. In an embodiment, the first electrode AND of each of the light-emitting elements LE may include titanium (Ti), titanium nitride (TiN), indium tin oxide (“ITO”), or indium zinc oxide (“IZO”), for example, but the embodiment of the disclosure is limited thereto.

The pixel defining film PDL may be disposed on a part of the first electrode AND of each of the light-emitting elements LE. The pixel defining film PDL may cover the edge of the first electrode AND of each of the light-emitting elements LE. The pixel defining film PDL may partition the first emission areas EA1, the second emission areas EA2, and the third emission areas EA3.

The pixel defining film PDL may include first to fourth pixel defining films PDL1, PDL2, PDL3, and PDL4.

The first pixel defining film PDL1 may be disposed on the first electrode AND of each of the light-emitting elements LE. Specifically, the first pixel defining film PDL1 may cover a part of the top surface of the first electrode AND disposed on the optical auxiliary film OAL. Further, the first pixel defining film PDL1 may cover the first electrode AND disposed on the side surface of the connection electrode ANC, the side surface of the reflective electrode RL, and the side surface of the optical auxiliary film OAL. The first pixel defining film PDL1 may be disposed on the top surface of the second portion AA2 of the ninth insulating film INS9.

A planarization film PNS is a film for flattening the stepped portion caused by the connection electrode ANC, the reflective electrode RL, and the optical auxiliary film OAL.

The planarization film PNS may be disposed on the first pixel defining film PDL1 covering the first electrode AND disposed on the side surface of the connection electrode ANC, the side surface of the reflective electrode RL, and the side surface of the optical auxiliary film OAL. The planarization film PNS may be disposed on the first pixel defining film PDL1 disposed on the second portion AA2 of the ninth insulating film INS9.

The planarization film PNS may be disposed between the connection electrodes ANC next (adjacent) to each other in the first direction DR1 or the second direction DR2. The planarization film PNS may be disposed between the reflective electrodes RL next (adjacent) to each other in the first direction DR1 or the second direction DR2. The planarization film PNS may be disposed between the optical auxiliary films OAL next (adjacent) to each other in the first direction DR1 or the second direction DR2.

The step layer STPL is not in the second emission area EA2, whereas the step layer STPL is in each of the first emission area EA1 and the third emission area EA3. Accordingly, the heights of the connection electrode ANC, the reflective electrode RL, and the optical auxiliary film OAL in the second emission area EA2 may be less than the heights of the connection electrode ANC, the reflective electrode RL, the step layer STPL, and the optical auxiliary film OAL in the first emission area EA1 and the third emission area EA3. Therefore, the planarization film PNS may cover the top surface of the first pixel defining film PDL1 disposed on the top surface of the first electrode AND disposed in the second emission area EA2.

In contrast, the top surface of the planarization film PNS may be flatly connected to the top surface of the first pixel defining film PDL1 disposed on the top surface of the first electrode AND disposed in the first emission area EA1 and the third emission area EA3. That is, the planarization film PNS may not cover the top surface of the first pixel defining film PDL1 disposed on the top surface of the first electrode AND disposed in each of the first emission area EA1 and the third emission area EA3.

The second pixel defining film PDL2 may be disposed on the first pixel defining film PDL1 and the planarization film PNS, the third pixel defining film PDL3 may be disposed on the second pixel defining film PDL2, and the fourth pixel defining film PDL4 may be disposed on the third pixel defining film PDL3. The first pixel defining film PDL1 and the third pixel defining film PDL3 may be formed as silicon nitride (SiNₓ)-based inorganic films, whereas the second pixel defining film PDL2, the fourth pixel defining film PDL4, and the planarization film PNS may be formed as silicon oxide (SiOₓ)-based inorganic films. The first pixel defining film PDL1 includes a material different from that of the planarization film PNS, and thus may serve as a stopper in a chemical mechanical polishing process for the planarization film PNS.

When the planarization film PNS and the second pixel defining film PDL2 are both formed as a silicon oxide (SiOₓ)-based inorganic film, the planarization film PNS and the second pixel defining film PDL2 may be formed as a single film.

Since the length of the third pixel defining film PDL3 in one direction is less than the length of the fourth pixel defining film PDL4 in one direction, the bottom surface (also referred to as a lower surface) of the fourth pixel defining film PDL4 may be exposed without being covered by the third pixel defining film PDL3. In some embodiments, the third pixel defining film PDL3 and the fourth pixel defining film PDL4 may have an eave-shaped or mushroom-shaped cross-sectional structure.

The light-emitting stack IL may be disposed on the first electrode AND and the pixel defining film PDL. The light-emitting stack IL may include the first stack layer IL1 and the second stack layer IL2 that emit different lights. When the light-emitting stack IL has a two-tandem structure, one of the first stack layer IL1 and the second stack layer IL2 may emit light that includes the wavelength range of any one of the first light, the second light, and the third light, and a remaining (the other) one of the first stack layer IL1 and the second stack layer IL2 may emit light that includes the wavelength ranges of remaining (the other) two lights. In an embodiment, the first stack layer IL1 may emit light that includes the wavelength range of the first light and the wavelength range of the third light, and the second stack layer IL2 may emit light that includes the wavelength range of the second light, for example. Here, the first light may be light of a blue wavelength band, the second light may be light of a green wavelength band, and the third light may be light of a red wavelength band.

A charge generation layer for supplying charges to the second stack layer IL2 and supplying electrons to the first stack layer IL1 may be disposed between the first stack layer IL1 and the second stack layer IL2. The charge generation layer may include an n-type charge generation layer that supplies electrons to the first stack layer IL1 and a p-type charge generation layer that supplies holes to the second stack layer IL2. The n-type charge generation layer may include a dopant of a metal material.

The first stack layer IL1 is not formed on the bottom surface of the fourth pixel defining film PDL4 that is exposed without being covered by the third pixel defining film PDL3, and thus may be cut off by the eaves-shaped or mushroom-shaped cross-sectional structure of the third pixel defining film PDL3 and the fourth pixel defining film PDL4. In this case, the first hole transport layer of the first stack layer IL1, and a charge generation layer disposed between the first stack layer IL1 and the second stack layer IL2 may also be cut off. Further, although FIG. 8 illustrates that the second stack layer IL2 is connected without being cut off, the second hole transport layer of the second stack layer IL2 may be cut off, and the second electron transport layer of the second stack layer IL2 may be connected without being cut off. Therefore, it is possible to prevent a leakage current from flowing through the first hole transport layer of the first stack layer IL1, the second hole transport layer of the second stack layer IL2, and the charge generation layer between the neighboring (adjacent) emission areas EA1, EA2, and EA3. Accordingly, it is possible to prevent the light-emitting stack IL in the neighboring (adjacent) emission areas EA1, EA2, and EA3 from emitting light other than the originally intended light due to the influence of the above current.

Although FIG. 8 illustrates a two-tandem structure in which the light-emitting stack IL includes two stack layers IL1 and IL2, the disclosure is not limited thereto. In an embodiment, the light-emitting stack IL may have a three-tandem structure including three stack layers as shown in FIG. 7, for example. In this case, it may be designed such that the charge generation layer between the first stack layer IL1 and the second stack layer IL2, and the charge generation layer between the second stack layer IL2 and the third stack layer IL3 are cut off by adjusting the height of the third pixel defining film PDL3. In an alternative embodiment, as shown in FIG. 7, the trench TRC penetrating the first pixel defining film PDL1, the planarization film PNS, the second pixel defining film PDL2, and the third pixel defining film PDL3 may be added. In this case, the trench TRC may penetrate at least a part of the ninth insulating film INS9, but the disclosure is not limited thereto.

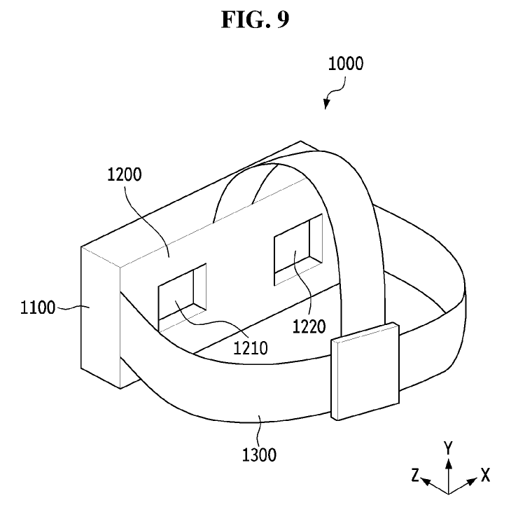

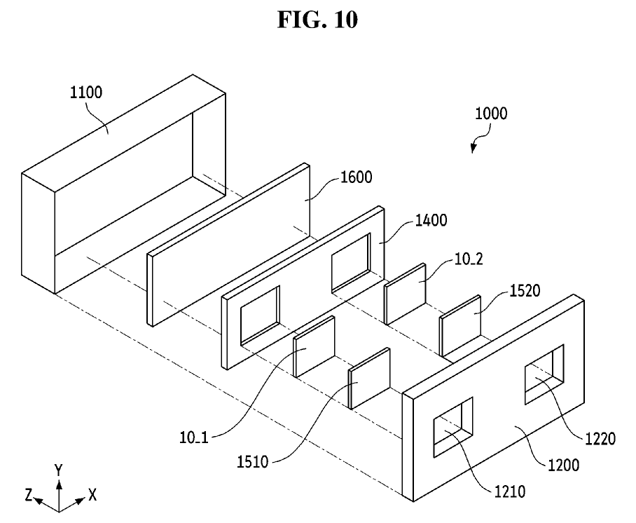

FIG. 9 is a perspective view illustrating an embodiment of a head mounted display. FIG. 10 is an exploded perspective view illustrating the head mounted display of FIG. 9.

Referring to FIGS. 9 and 10, a head mounted display 1000 in an embodiment includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. Since each of the first display device 10_1 and the second display device 10_2 is substantially the same as the display device 10 described in conjunction with FIGS. 1 to 8, the description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. In an alternative embodiment, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is disposed and the second eyepiece 1220 at which the user's right eye is disposed. FIGS. 9 and 10 illustrate that the first eyepiece 1210 and the second eyepiece 1220 are disposed separately, but the disclosure is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

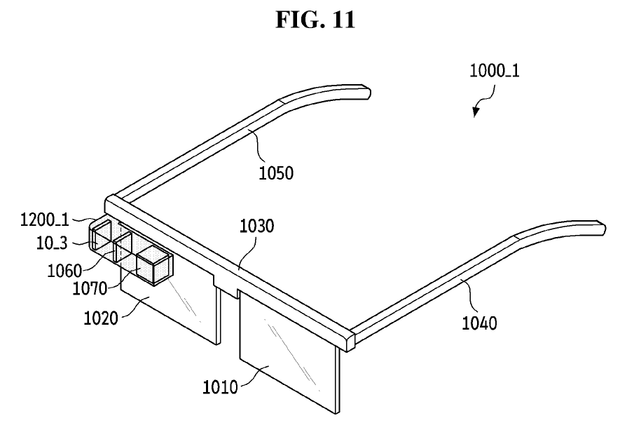

The head mounted band 1300 serves to secure the display device housing 1100 to the user's head such that the first eyepiece 1210 and the second eyepiece 1220 of the housing cover 1200 remain disposed on the user's left and right eyes, respectively. When the display device housing 1100 is implemented to be lightweight and compact, the head mounted display 1000 may be provided with, as shown in FIG. 11, an eyeglass frame instead of the head mounted band 1300.

FIG. 11 is a perspective view illustrating another embodiment of a head mounted display.

Referring to FIG. 11, a head mounted display 1000_1 in an embodiment may be an eyeglasses-type display device in which a display device housing 1200_1 is implemented in a lightweight and compact manner. The head mounted display 1000_1 in an embodiment may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060, and may be provided to the user's right eye through the right eye lens 1020 after the optical path is changed by the optical path changing member 1070. As a result, the user may view an augmented reality image, through the right eye, in which a virtual image displayed on the display device 10_3 and a real image seen through the right eye lens 1020 are combined.

FIG. 11 illustrates that the display device housing 1200_1 is disposed at the right end of the support frame 1030, but the disclosure is not limited thereto. In an embodiment, the display device housing 1200_1 may be disposed at the left end of the support frame 1030, and in this case, the image of the display device 10_3 may be provided to the user's left eye, for example. In an alternative embodiment, the display device housing 1200_1 may be disposed at both the left and right ends of the support frame 1030, and in this case, the user may view the image displayed on the display device 10_3 through both the left and right eyes.

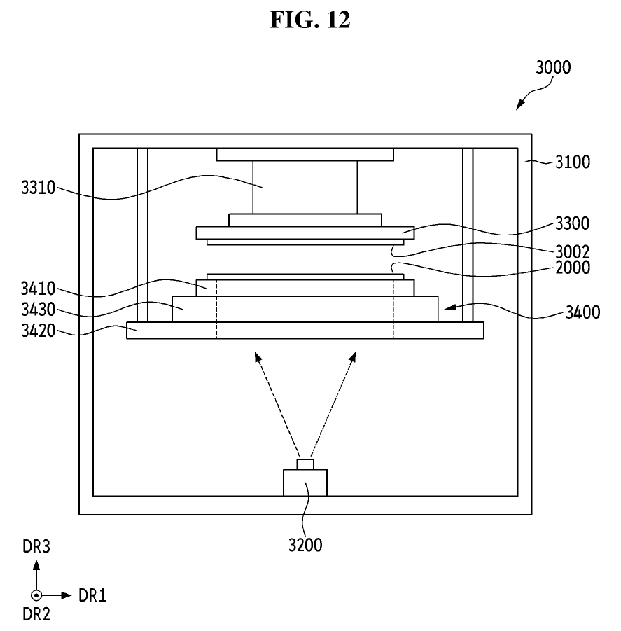

FIG. 12 is a schematic diagram illustrating an embodiment of a deposition apparatus.

Referring to FIG. 12, a deposition apparatus 3000 may be used to form light-emitting material layers on a backplane substrate 3002 in a manufacturing process of the display panel 100 (refer to FIG. 1). In an embodiment, as illustrated in FIG. 7, the semiconductor backplane SBP and the light-emitting element backplane EBP may be disposed on the backplane substrate 3002, and the reflective electrode RL and the tenth insulating film INS10 may be disposed on the light-emitting element backplane EBP, for example. An eleventh insulating film INS11 may be disposed on the tenth insulating film INS10, electrode patterns, e.g., anode electrodes AND may be disposed on the eleventh insulating film INS11, and the anode electrodes AND may be electrically connected to the reflective electrode RL through the tenth vias VA10. The deposition apparatus 3000 may be used to form the light-emitting stack IL on the electrode patterns.

The deposition apparatus 3000 may include a deposition source 3200 for providing a vapor deposition material on the backplane substrate 3002, a deposition mask 2000 disposed above the deposition source 3200, and a substrate chuck 3300 disposed above the deposition mask 2000 to support the backplane substrate 3002 such that the backplane substrate 3002 faces the deposition mask 2000. That is, the substrate chuck 3300 may support the backplane substrate 3002 such that the front surface of the backplane substrate 3002 faces downward, and may position the backplane substrate 3002 above the deposition mask 2000 to perform a deposition process. The substrate chuck 3300 may be supported by a support member 3310 and a permanent magnet (not shown) may be disposed inside the support member 3310.

The deposition source 3200, the deposition mask 2000, and the substrate chuck 3300 may be disposed in a process chamber 3100. The process chamber 3100 may have an internal space, and a deposition process for forming a deposition material layer on the backplane substrate 3002 may be performed in the internal space of the process chamber 3100. Although not shown, the process chamber 3100 may be connected to a vacuum pump (not shown), and the internal space of the process chamber 3100 may be set to a vacuum atmosphere by the vacuum pump. An opening (not shown) for the carry-in and carry-out of the backplane substrate 3002 and the deposition mask 2000 may be defined in a wall of the process chamber 3100, and the opening may be opened and closed by a gate valve (not shown).

A deposition material may be accommodated in the deposition source 3200. The deposition source 3200 may evaporate a deposition material such as an organic material, an inorganic material, a conductive material, or the like toward the backplane substrate 3002, and the evaporated deposition material may be deposited on the backplane substrate 3002 through the deposition mask 2000. In an embodiment, the deposition source 3200 may evaporate an organic material for forming light-emitting material layers on the backplane substrate 3002, and the evaporated organic material may be deposited on the electrode patterns on the backplane substrate 3002 through the deposition mask 2000, for example. In an embodiment, the deposition apparatus 3000 may further include a mask chuck driver 3400 on which the deposition mask 2000 is disposed. The mask chuck driver 3400 may include a mask chuck 3410, a mask stage 3420 and a piezo actuator 3430, for example.

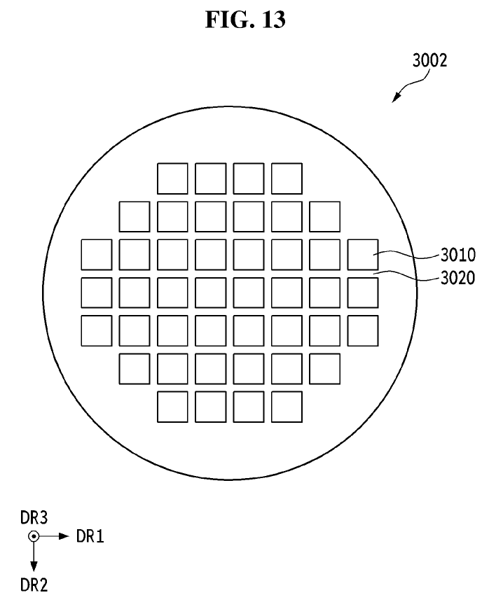

FIG. 13 is a schematic bottom view illustrating the backplane substrate shown in FIG. 12.

Referring to FIG. 13, the backplane substrate 3002 may include a plurality of display cell regions 3010 and a scribe lane region 3020 disposed between the display cell regions 3010. The display cell regions 3010 may be arranged in a matrix form along the first direction DR1 and the second direction DR2 as illustrated in FIG. 13, and each of the display cell regions 3010 may be individualized into a plurality of display panels 100 (refer to FIG. 1) by a dicing process after the display manufacturing process is completed. In an embodiment, the display cell regions 3010 may be arranged in a matrix form along the first horizontal direction DR1 and the second horizontal direction DR2 perpendicular to the first horizontal direction DR1, for example.

Each of the display cell regions 3010 may include the semiconductor backplane SBP, the light-emitting element backplane EBP disposed on the semiconductor backplane SBP, the reflective electrode RL disposed on the light-emitting element backplane EBP, and the eleventh insulating film INS11 disposed on the reflective electrode RL. In addition, each of the display cell regions 3010 may include the plurality of electrode patterns, e.g., the plurality of anode electrodes AND disposed on the eleventh insulating film INS11, and the anode electrodes AND may be connected to the reflective electrode RL through the plurality of tenth vias VA10. In this case, the electrode patterns of the display cell regions 3010 may be disposed on the front surface of the backplane substrate 3002, and the substrate chuck 3300 may hold the rear surface of the backplane substrate 3002 such that the electrode patterns of the display cell regions 3010 face downward, i.e., face the deposition source 3200.

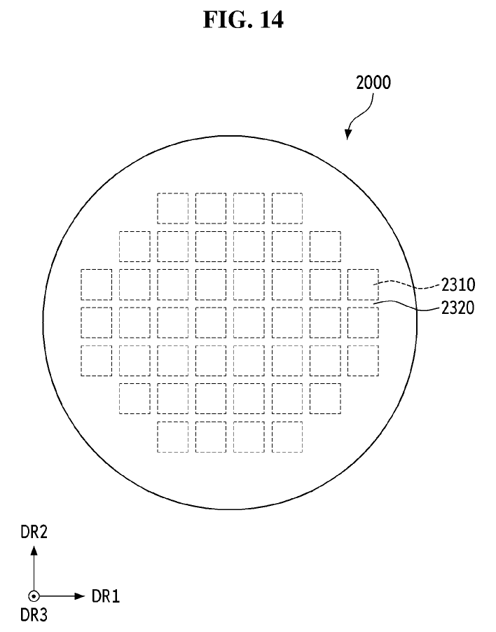

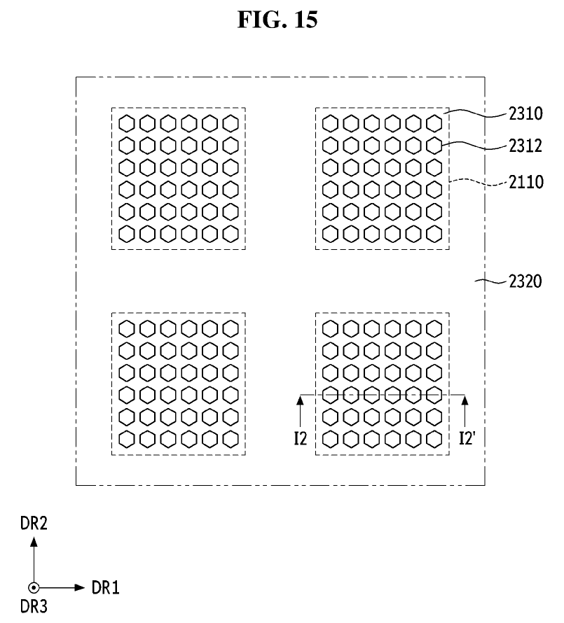

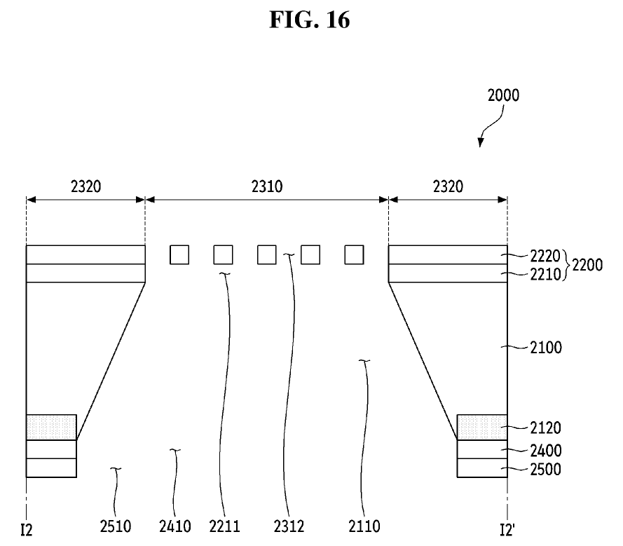

FIG. 14 is a schematic plan view illustrating an embodiment of a deposition mask according to the disclosure. FIG. 15 is a schematic enlarged plan view illustrating the mask cell regions shown in FIG. 14. FIG. 16 is a schematic cross-sectional view illustrating a first embodiment of a deposition mask taken along line I2-I2’ of FIG. 15.

Referring to FIGS. 14 to 16, the deposition mask 2000 in an embodiment of the disclosure may include a mask frame 2100, a doping layer 2120, a membrane 2200, a first rear inorganic layer 2400, and a second rear inorganic layer 2500.

The mask frame 2100 may define a plurality of cell openings 2110. The mask frame 2100 may be provided as a single crystal silicon substrate, and the cell openings 2110 may be defined by a wet etching process using tetramethyl ammonium hydroxide (“TMAH”), or potassium hydroxide (“KOH”). The crystal orientation of the single crystal silicon substrate provided as the mask frame 2100 may be in the third direction DR3.

The cell opening 2110 is an area where a portion of the mask frame 2100 is removed, and may extend in the thickness direction of the mask frame 2100 from the bottom surface (also referred to as a lower surface) of the mask frame 2100 to penetrate the mask frame 2100. In some embodiments, the cell opening 2110 may extend toward the membrane 2200 from the bottom surface of the mask frame 2100 to penetrate the mask frame 2100. The cross-sectional area of the cell opening 2110 in the horizontal direction may be gradually reduced from the bottom to the top of the mask frame 2100. In some embodiments, the cross-sectional area of the lower end of the cell opening 2110 may be larger than the area of the upper end thereof.

The doping layer 2120 may extend in the thickness direction of the mask frame 2100 from the bottom surface of the mask frame 2100. The doping layer 2120 may be disposed to surround the bottom side of the cell opening 2110 in the lower area of the mask frame 2100. Since the doping layer 2120 is disposed to surround the bottom side of the cell opening 2110, the cell opening 2110 may extend in the thickness direction of the mask frame 2100 from the side of the bottom surface (also referred to as a lower surface) of the doping layer 2120.

The doping layer 2120 may be formed in the mask frame 2100 by one doping process among P (positive) doping process and N (negative) doping process. In an embodiment, when the doping layer 2120 is formed by the P doping process, the doping layer 2120 may be formed by doping the mask frame 2100 with one or more elements selected from boron (B) and aluminum (Al), for example. In addition, when the doping layer 2120 is formed by the N doping process, the doping layer 2120 may be formed by doping the mask frame 2100 with one or more elements selected from phosphorus (P), arsenic (As), and antimony (Sb).

Since the doping layer 2120 extends in the thickness direction of the mask frame 2100 from the bottom surface of the mask frame 2100, the bottom surface of the doping layer 2120 may form the same surface as the bottom surface of the mask frame 2100. The bottom surface of the doping layer 2120 may contact the top surface of the first rear inorganic layer 2400 disposed below the mask frame 2100. The doping layer 2120 may overlap a grid area 2320 of the membrane 2200 to be described later.

The membrane 2200 may be disposed above the mask frame 2100. The membrane 2200 may include the mask cell regions 2310 respectively corresponding to the display cell regions 3010 of the backplane substrate 3002 and a grid region 2320 excluding the mask cell regions 2310.

As shown in FIG. 14, the mask cell regions 2310 may be arranged in a matrix form along the first direction DR1 and the second direction DR2. In an embodiment, the mask cell regions 2310 may be arranged in a matrix form along the first horizontal direction DR1 and the second horizontal direction DR2 perpendicular to the first horizontal direction DR1, and may be arranged to respectively correspond to the display cell regions 3010 of the backplane substrate 3002, for example. The grid region 2320 may be a region of the membrane 2200 excluding the mask cell regions 2310.

The membrane 2200 may include an inorganic layer 2210 and a nitride layer 2220.

The inorganic layer 2210 may be disposed above the mask frame 2100. In some embodiments, the inorganic layer 2210 may be disposed above the mask frame 2100 so that the bottom surface (also referred to as a lower surface) of the inorganic layer 2210 contacts the top surface of the mask frame 2100. The inorganic layer 2210 may include a material that has an etching selectivity with respect to the nitride layer 2220 and the mask frame 2100. In an embodiment, the inorganic layer 2210 may include silicon oxide (SiOₓ), for example.

The inorganic layer opening 2211 may be defined in the inorganic layer 2210. The inorganic layer opening 2211 may be an area where a portion of the inorganic layer 2210 is removed. The inorganic layer opening 2211 may be defined by a wet etching process using TMAH, or KOH. The inorganic layer opening 2211 may be connected to the cell opening 2110.

The nitride layer 2220 may be disposed on the inorganic layer 2210. In some embodiments, the nitride layer 2220 may be disposed on the inorganic layer 2210 so that the bottom surface (also referred to as a lower surface) of the nitride layer 2220 contacts the top surface of the inorganic layer 2210. The nitride layer 2220 may include silicon nitride (SiNₓ).

A plurality of pixel openings 2312 may be defined in the nitride layer 2220. The plurality of pixel openings 2312 may be an area where a portion of the nitride layer 2220 is removed. The plurality of pixel openings 2312 may expose anode electrodes AND in a deposition process. The plurality of pixel openings 2312 may be exposed toward a deposition source 3200 through an inorganic layer opening 2211 and the cell opening 2110. The plurality of pixel openings 2312 may be connected to the cell opening 2110 through the inorganic layer opening 2211.

The first rear inorganic layer 2400 may be disposed below the mask frame 2100. In some embodiments, the first rear inorganic layer 2400 may be disposed below the mask frame 2100 so that the top surface of the first rear inorganic layer 2400 contacts the bottom surface of the mask frame 2100. A first rear opening 2410 connected to the cell opening 2110 may be defined in the first rear inorganic layer 2400. The first rear opening 2410 may be an area where a portion of the first rear inorganic layer 2400 is removed. The first rear opening 2410 may be defined by a wet etching process using TMAH, or KOH. The first rear inorganic layer 2400 may overlap the doping layer 2120.

The second rear inorganic layer 2500 may be disposed below the first rear inorganic layer 2400. In some embodiments, the second rear inorganic layer 2500 may be disposed below the first rear inorganic layer 2400 so that the top surface of the second rear inorganic layer 2500 contacts the bottom surface (also referred to as a lower surface) of the first rear inorganic layer 2400. A second rear opening 2510 connected to the cell opening 2110 and the first rear opening 2410 may be defined in the second rear inorganic layer 2500. The second rear opening 2510 may be an area where a portion of the second rear inorganic layer 2500 is removed. The second rear opening 2510 may be defined by a wet etching process using TMAH, or KOH. The second rear inorganic layer 2500 may overlap the doping layer 2120.

Hereinafter, a manufacturing method of the deposition mask in an embodiment of the disclosure will be described with reference to the drawings.

In the manufacturing method of a deposition mask in an embodiment of the disclosure may include an operation of forming the inorganic layer 2210 above the mask frame 2100 and forming the first rear inorganic layer 2400 below the mask frame 2100, an operation of exposing a portion of the mask frame 2100 to the outside by removing a portion of the first rear inorganic layer 2400, an operation of forming the doping layer 2120 by doping the exposed portion of the mask frame 2100, an operation of forming the first rear inorganic layer 2400 to cover the exposed portion of the mask frame 2100, an operation of forming the nitride layer 2220 above the inorganic layer 2210 and forming the second rear inorganic layer 2500 below the first rear inorganic layer 2400, an operation of defining the first rear opening 2410 to penetrate the first rear inorganic layer 2400 and forming the second rear opening 2510 to penetrate the second rear inorganic layer 2500, an operation of defining the plurality of pixel openings 2312 to penetrate the nitride layer 2220, an operation of defining the cell opening 2110 to penetrate the mask frame 2100, and an operation of defining the inorganic layer opening 2211 to penetrate the inorganic layer 2210.

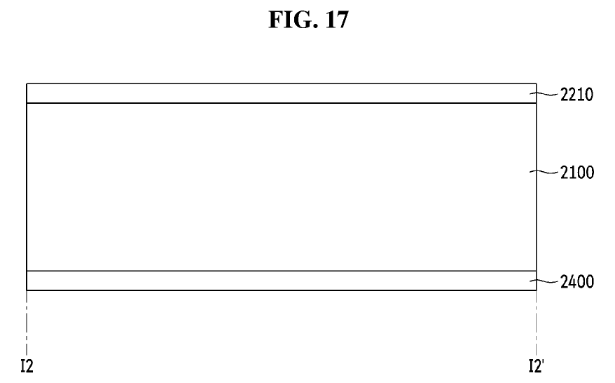

FIG. 17 is a diagram showing an embodiment of a state in which an inorganic layer and a first rear inorganic layer are formed on the upper and lower portions of a mask frame in a manufacturing method of a deposition mask according to the disclosure.

Referring to FIG. 17, in the operation of forming the inorganic layer 2210 above the mask frame 2100 and forming the first rear inorganic layer 2400 below the mask frame 2100, the inorganic layer 2210 may be formed above the mask frame 2100 through a deposition process, and the first rear inorganic layer 2400 may be formed below the mask frame 2100 through a deposition process.

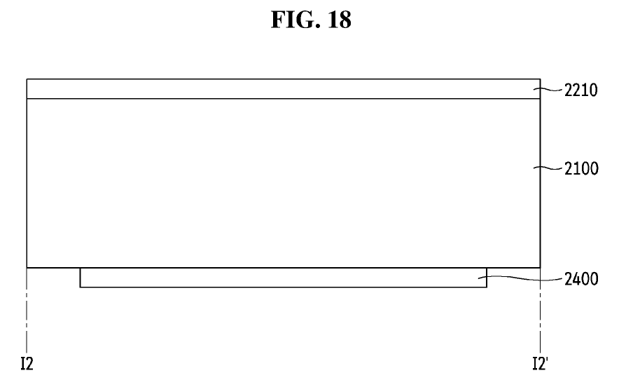

FIG. 18 is a diagram showing a state in which a portion of the first rear inorganic layer is removed in FIG. 17.

Referring to FIG. 18, the operation of exposing a portion of the mask frame 2100 to the outside by removing the portion of the first rear inorganic layer 2400 may be an operation of removing a portion of the first rear inorganic layer 2400 through a wet etching process. The removed area of the first rear inorganic layer 2400 may be an area not overlapping with the cell opening 2110 of the mask frame 2100. In the operation of exposing a portion of the mask frame 2100 to the outside by removing the portion of the first rear inorganic layer 2400, the portion of the first rear inorganic layer 2400 may be removed by a wet etching process using TMAH, or KOH. The portion of the mask frame 2100 exposed to the outside through the wet etching process may be a portion where the cell opening 2110 is not defined.

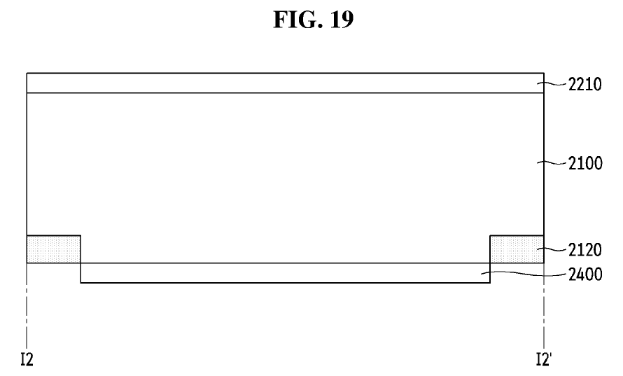

FIG. 19 is a diagram showing a state in which a doping layer is formed on a mask frame in FIG. 18.

Referring to FIG. 19, the operation of forming the doping layer 2120 by doping the exposed portion of the mask frame 2100 may be an operation of forming the doping layer 2120 by applying a doping process on the exposed portion of the mask frame 2100. The doping process applied to the mask frame 2100 may be one doping process among the P (positive) process and N (negative) process. In an embodiment, when the doping layer 2120 is formed through a P doping process, the doping layer 2120 may be formed by doping the mask frame 2100 with one or more elements selected from boron (B) and aluminum (Al), for example. In addition, when the doping layer 2120 is formed by the N doping process, the doping layer 2120 may be formed by doping the mask frame 2100 with one or more elements selected from phosphorus (P), arsenic (As), and antimony (Sb).

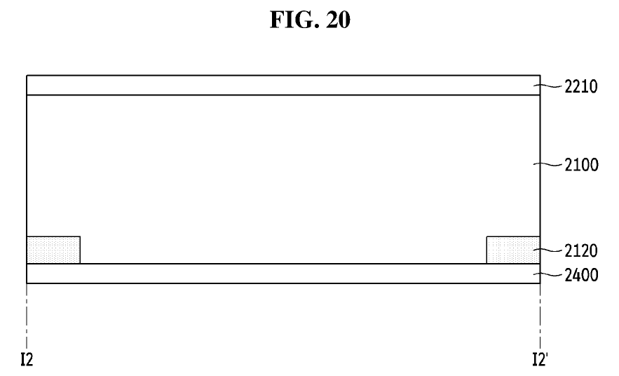

FIG. 20 is a diagram showing a state in which the first rear inorganic layer is formed to cover the doping layer in FIG. 19.

Referring to FIG. 20, in the operation of forming the first rear inorganic layer 2400 to cover the exposed portion of the mask frame 2100, the first rear inorganic layer 2400 may be formed on the lower portion of the exposed portion of the mask frame 2100 through a deposition process. In some embodiments, the first rear inorganic layer 2400 may be formed below the doping layer 2120 to cover the doping layer 2120.

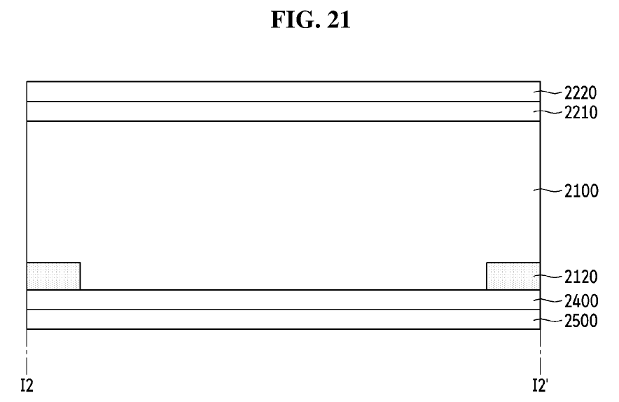

FIG. 21 is a diagram showing a state in which a nitride layer is formed above the inorganic layer and a second rear inorganic layer is formed below the first rear inorganic layer in FIG. 20.

Referring to FIG. 21, in the operation of forming the nitride layer 2220 above the inorganic layer 2210 and forming the second rear inorganic layer 2500 below the first rear inorganic layer 2400, the nitride layer 2220 may be formed above the inorganic layer 2210 through a deposition process and the second rear inorganic layer 2500 may be formed below the first rear inorganic layer 2400 through a deposition process.

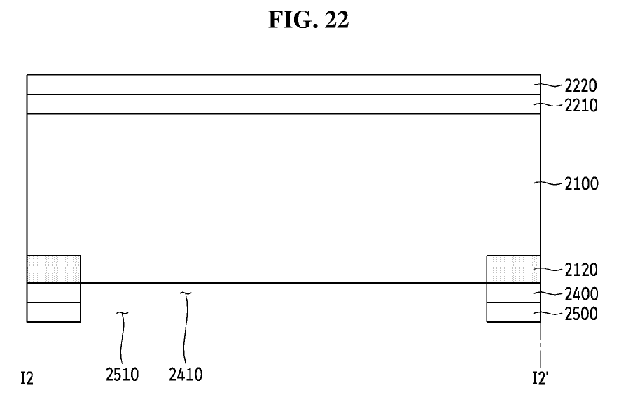

FIG. 22 is a diagram showing a state in which a first rear opening and a second rear opening are defined in FIG. 21.

Referring to FIG. 22, the operation of defining the first rear opening 2410 to penetrate the first rear inorganic layer 2400 and defining the second rear opening 2510 to penetrate the second rear inorganic layer 2500 may be defining the second rear opening 2510 by etching a portion of the second rear inorganic layer 2500 and defining the first rear opening 2410 by etching a portion of the first rear inorganic layer 2400 through a wet etching process from below the second rear inorganic layer 2500 to the insides of the second rear inorganic layer 2500 and the first rear inorganic layer 2400. In the operation of defining the first rear opening 2410 to penetrate the first rear inorganic layer 2400 and defining the second rear opening 2510 to penetrate the second rear inorganic layer 2500, since TMAH, or KOH is permeated from below the second rear inorganic layer 2500, the second rear opening 2510 and the first rear opening 2410 may be sequentially defined.

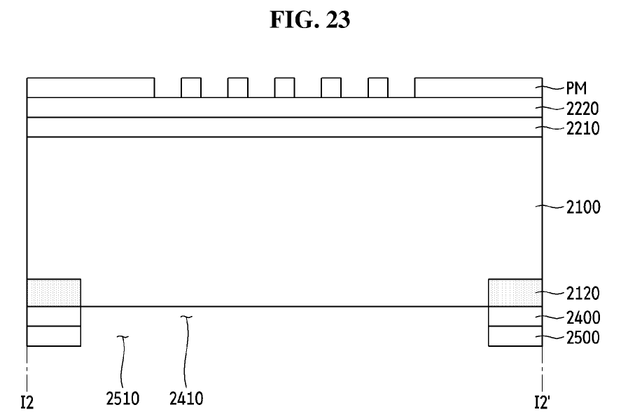

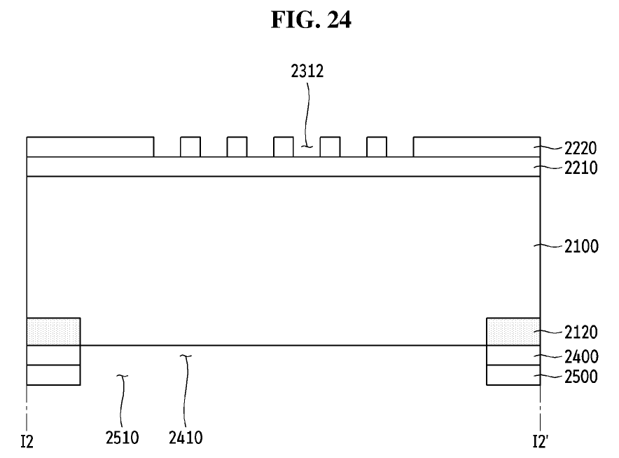

FIG. 23 is a diagram showing a state in which a photo mask is disposed above the nitride layer in FIG. 22. FIG. 24 is a diagram showing a state in which a plurality of pixel openings is formed in the nitride layer in FIG. 23.

Referring to FIGS. 23 and 24, the operation of defining the plurality of pixel openings 2312 to penetrate the nitride layer 2220 may be an operation of defining the plurality of pixel openings 2312 by penetrating the nitride layer 2220 by a wet etching process from above the nitride layer 2220 to the inside of the nitride layer 2220.

In the operation of defining the plurality of pixel openings 2312 to penetrate the nitride layer 2220, a photo mask PM in which patterns corresponding to the plurality of pixel openings 2312 are defined may be disposed above the nitride layer 2220, and TMAH, or KOH may be permeated into the pattern of the photo mask PM to etch the nitride layer 2220. The plurality of pixel openings 2312 may be defined by removing a portion of the nitride layer 2220 by an etching process.

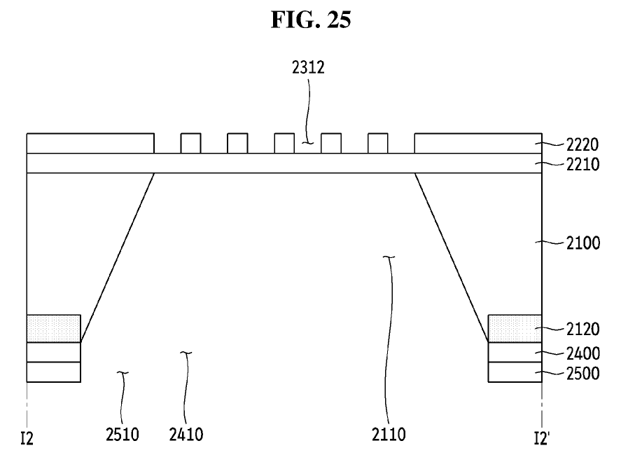

FIG. 25 is a diagram showing a state in which a cell opening is defined in FIG. 24.

Referring to FIG. 25, the operation of defining the cell opening 2110 to penetrate the mask frame 2100 may be an operation of defining the cell opening 2110 by penetrating the mask frame 2100 by a wet etching process from below the mask frame 2100 to the inside of the mask frame 2100.

In the operation of defining the cell opening 2110 to penetrate the mask frame 2100, the mask frame 2100 may be etched by infiltrating TMAH, or KOH into the lower portion of the mask frame 2100, thereby defining the cell opening 2110. In the operation of etching the mask frame 2100, since the etch rate of the mask frame 2100 is higher than the etch rate of the doping layer 2120, etching of the mask frame 2100 in the horizontal direction may be blocked by the doping layer 2120, thereby limiting etching of the mask frame 2100 in the horizontal direction. In some embodiments, since the etching of the doping layer 2120 is slowly etched in the horizontal direction of the mask frame 2100, the cell opening 2110 may be defined in a state of not overlapping the first rear inorganic layer 2400 and the second rear inorganic layer 2500. Accordingly, the first rear inorganic layer 2400 and the second rear inorganic layer 2500 may be prevented from protruding in the inner side of the cell opening 2110.

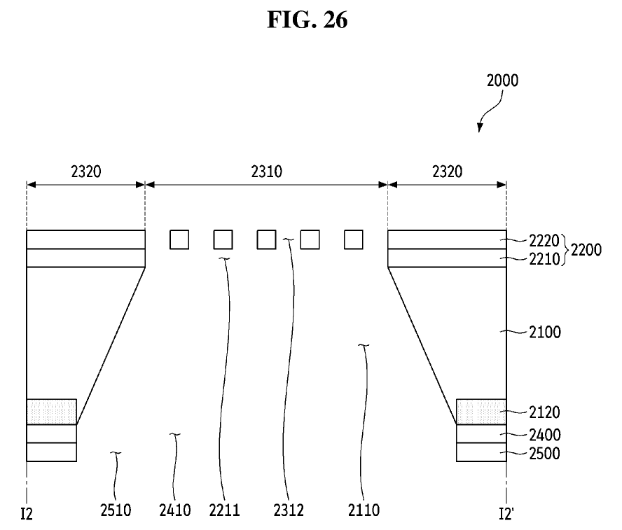

FIG. 26 is a diagram showing a state in which an inorganic layer opening is defined in FIG. 25.

Referring to FIG. 26, the operation of defining the inorganic layer opening 2211 to penetrate the inorganic layer 2210 may be an operation of defining the inorganic layer opening 2211 by penetrating the inorganic layer 2210 through a wet etching process from below the inorganic layer 2210 to the inside of the inorganic layer 2210.

In the operation of defining the inorganic layer opening 2211 to penetrate the inorganic layer 2210, TMAH, or KOH may be permeated from below the inorganic layer 2210 to etch the inorganic layer 2210. The inorganic layer 2210 may be formed by removing a portion of the inorganic layer 2210 through an etching process.

The display device manufactured by a deposition mask 2000 in the embodiment of the disclosure may be applied to various electronic devices. An electronic device in an embodiment includes the above-described display device and may further include modules or devices having other additional functions, in addition to the display device.

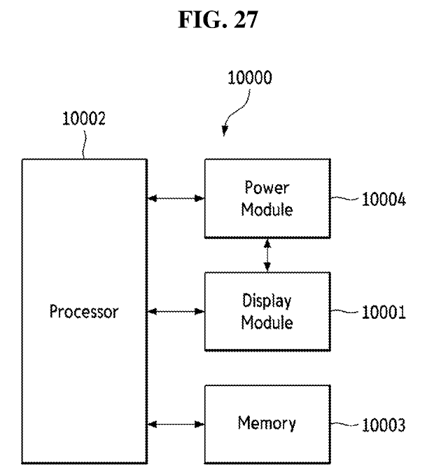

FIG. 27 is a block diagram of an embodiment of an electronic device.

Referring to FIG. 27, an electronic device 10000 in an embodiment may include a display module 10001, a processor 10002, a memory 10003, and a power module 10004.

The processor 10002 may include at least one of a central processing unit (“CPU”), an application processor (“AP”), a graphic processing unit (“GPU”), a communication processor (“CP”), an image signal processor (“ISP”), or a controller.

The memory 10003 may store data information desired for the operation of the processor 10002 or the display module 10001. When the processor 10002 executes an application stored in the memory 10003, an image data signal and/or an input control signal is transmitted to the display module 10001, and the display module 10001 may process the received signal and output image information through a display screen.

The power module 10004 may include a power supply module, such as a power adapter or a battery device, and a power conversion module that converts power supplied by the power supply module to generate power desired for the operation of the electronic device 10000.

At least one of the components of the electronic device 10000 described above may be included in the display device in the embodiments described above. Further, some of individual modules functionally included in one module may be included in the display device and some others may be provided separately from the display device. In an embodiment, the display device may include the display module 10001, and the processor 10002, the memory 10003, and the power module 10004 may be provided in the form of other devices in the electronic device 10000 other than the display device, for example.

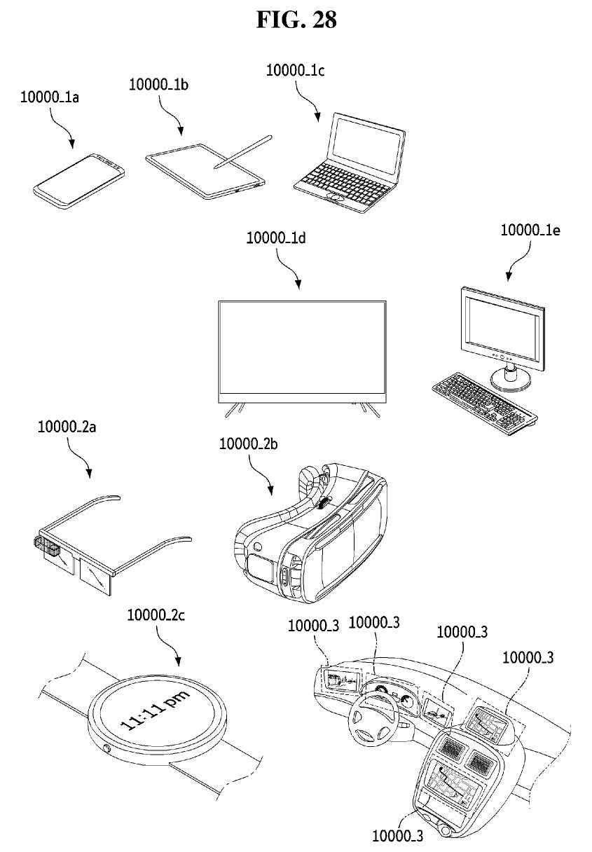

FIG. 28 is schematic views of embodiments of electronic devices.

Referring to FIG. 28, various electronic devices to which the display devices in the embodiments are applied may include not only an image display electronic device such as a smartphone 10000_1a, a tablet PC 10000_1b, a laptop 10000_1c, a television (“TV”) 10000_1d, and a desk monitor 10000_1e, but also a wearable electronic device including a display module such as smart glasses 10000_2a, a head mounted display 10000_2b, and a smart watch 10000_2c, and a vehicle electronic device 10000_3 including a display module such as a room mirror display, a center information display (“CID”) placed on a dashboard, a center fascia, and an instrument panel of a car.

It should be understood, however, that the advantages and features of embodiments of the disclosure are not restricted to the one set forth herein. The above and other features of the disclosure will become more apparent to one of ordinary skill in the art to which the disclosure pertains by referencing the claims, with equivalents thereof to be included therein.

What is claimed is:

1. A deposition mask comprising:
a mask frame in which a cell opening is defined;
a membrane disposed above the mask frame; and
a doping layer extending in a thickness direction of the mask frame from a lower surface of the mask frame.

2. The deposition mask of claim 1,
wherein the cell opening extends toward the membrane from the lower surface of the mask frame, and
the doping layer surrounds a lower end of the cell opening.

3. The deposition mask of claim 1,
wherein the cell opening extends toward the membrane from the side of the lower surface of the doping layer, and
a cross-sectional area of the cell opening in a horizontal direction is reduced toward the membrane.

4. The deposition mask of claim 1,
wherein the membrane is divided into a mask cell region disposed above the cell opening and a grid region disposed above the mask frame excluding the cell opening, and
the doping layer overlaps the grid region.

5. The deposition mask of claim 1, further comprising:
a first rear inorganic layer disposed below the mask frame and in which a first rear opening is defined; and
a second rear inorganic layer disposed below the first rear inorganic layer and in which a second rear opening is defined,
wherein the doping layer overlaps the first rear inorganic layer and the second rear inorganic layer.

6. The deposition mask of claim 5,
wherein a lower surface of the doping layer contacts a top surface of the first rear inorganic layer.

7. The deposition mask of claim 5,
wherein the cell opening overlaps the first rear opening and the second rear opening.

8. The deposition mask of claim 1,
wherein the membrane comprises:
an inorganic layer disposed above the mask frame and in which an inorganic layer opening is defined; and
a nitride layer disposed above the inorganic layer and in which a plurality of pixel openings are defined,
wherein the inorganic layer opening and the plurality of pixel openings overlap the cell opening.

9. The deposition mask of claim 1,
wherein the doping layer is formed by doping the mask frame with one or more selected elements from boron (B), aluminum (Al), phosphorus (P), arsenic (As), and antimony (Sb).

10. A manufacturing method of a deposition mask, the manufacturing method comprising:
forming an inorganic layer above a mask frame and forming a first rear inorganic layer below the mask frame;
exposing a portion of the mask frame to the outside by removing a portion of the first rear inorganic layer;
forming a doping layer by doping the exposed portion of the mask frame;
forming the first rear inorganic layer to cover the exposed portion of the mask frame;
forming a nitride layer above the inorganic layer and forming a second rear inorganic layer below the first rear inorganic layer;
defining a first rear opening to penetrate the first rear inorganic layer and forming a second rear opening to penetrate the second rear inorganic layer;
defining a plurality of pixel openings to penetrate the nitride layer;
defining a cell opening to penetrate the mask frame; and
defining an inorganic layer opening to penetrate the inorganic layer.

11. The manufacturing method of claim 10,
wherein the exposing the portion of the mask frame to the outside by removing the portion of the first rear inorganic layer is removing the portion of the first rear inorganic layer by a wet etching process, and
the portion of the mask frame exposed to the outside is a portion where the cell opening is not defined.

12. The manufacturing method of claim 10,
wherein the forming the doping layer by doping the exposed portion of the mask frame is forming the doping layer by doping the mask frame with one or more elements selected from boron (B), aluminum (Al), phosphorus (P), arsenic (As), and antimony (Sb).

13. The manufacturing method of claim 10,
wherein the forming the first rear inorganic layer to cover the exposed portion of the mask frame is forming the first rear inorganic layer below the mask frame to cover the exposed portion of the mask frame.

14. The manufacturing method of claim 10,
wherein the defining the first rear opening to penetrate the first rear inorganic layer and defining the second rear opening to penetrate the second rear inorganic layer is defining the second rear opening by penetrating the second rear inorganic layer and defining the first rear opening by penetrating the first rear inorganic layer through a wet etching process from below the second rear inorganic layer to insides of the second rear inorganic layer and the first rear inorganic layer.

15. The manufacturing method of claim 10,
wherein the defining the plurality of pixel openings to penetrate the nitride layer is defining the plurality of pixel openings by penetrating the nitride layer by a wet etching process from above the nitride layer to the inside of the nitride layer.

16. The manufacturing method of claim 10,
wherein the defining the cell opening to penetrate the mask frame is defining the cell opening by penetrating the mask frame by a wet etching process from below the mask frame to the inside of the mask frame.

17. The manufacturing method of claim 16,
wherein, in the defining the cell opening to penetrate the mask frame,
an etching of the mask frame is confined by the doping layer to confine an etching of the mask frame in a horizontal direction.

18. The manufacturing method of claim 10,
wherein the defining the inorganic layer opening to penetrate the inorganic layer is defining the inorganic layer opening by penetrating the inorganic layer through a wet etching process from below the inorganic layer to the inside of the inorganic layer.

19. An electronic device comprising:
a display device manufactured using a deposition mask, the deposition mask comprising:
a mask frame in which a cell opening is defined;
a membrane disposed above the mask frame; and
a doping layer extending in a thickness direction of the mask frame from a lower surface of the mask frame.

20. The electronic device of claim 19,
wherein the cell opening extends from the lower surface of the mask frame toward the membrane, and
the doping layer surrounds a lower end of the cell opening.
